(19) United States
(12) Patent Application Publication
(10) Pub. No.: US 2013/0100324 A1
(43) Pub. Date: Apr. 25, 2013

(54) METHOD OF MANUFACTURING SOLID-STATE IMAGE PICKUP ELEMENT, SOLID-STATE IMAGE PICKUP ELEMENT, IMAGE PICKUP DEVICE, ELECTRONIC APPARATUS, SOLID-STATE IMAGE PICKUP DEVICE, AND METHOD OF MANUFACTURING SOLID-STATE IMAGE PICKUP DEVICE

(71) Applicant: Sony Corporation, Tokyo (JP)

(72) Inventors: Akiko Ogino, Kumamoto (JP); Atsushi Yamamoto, Kumamoto (JP); Yoichi Ootsuka, Kumamoto (JP); Yoshinori Toumiya, Kumamoto (JP)

(73) Assignee: SONY CORPORATION, Tokyo (JP)

(21) Appl. No.: 13/649,524

(22) Filed: Oct. 11, 2012

(30) Foreign Application Priority Data
Oct. 21, 2011 (JP) 2011-231640
Nov. 30, 2011 (JP) 2011-262101
Dec. 8, 2011 (JP) 2011-268895

(51) Int. Cl. H01L 31/0232; H01L 31/18; H04N 5/335

(52) U.S. Cl. 348/294; 438/69; 257/432; 438/70; 348/E05.091; 257/E31.127

(57) ABSTRACT

Disclosed herein is a method of manufacturing a solid-state image pickup element having a lens provided above a light receiving portion. The manufacturing method includes: forming a lens base material layer composing the lens; forming an intermediate film having a thermal expansion coefficient larger than that of a resist on the lens base material layer; forming the resist in contact with the intermediate film; forming the resist into a lens shape by thermal reflow; and transferring the lens shape of the resist to the lens base material layer by etching, thereby forming the lens.

### BACKGROUND

The present disclosure relates to a method of manufacturing a solid-state image pickup element, a solid-state image pickup element manufactured by the manufacturing method, an image pickup device including the solid-state image pickup element, and an electronic apparatus including the image pickup device.

In a solid-state image pickup element, for the purpose of increasing a light condensing efficiency to increase a quantity of light received in a light receiving portion composed of a photodiode of each of pixels, a microlenses are provided above the light receiving portion of each of the pixels.

Also, as far as the light condensing concerned in the solid-state image pickup element, it is important that the contribution by the microlenses is large and a non-effective area in which any of the microlenses does not contribute to the light condensing is reduced.

On the other hand, in order to enhance light gathering power of lens, lens materials such as a high-refractive index material, and a low-refractive index material for suppressing reflection in a lens interface have been increased in variation, and thus it has become difficult to control a lens shape.

A technique for forming a microlens roughly includes three methods: (1) a resist etchback method; (2) an etchbackless method; and (3) a nanoimprint method.

In the resist etchback method described in (1), for the purpose of realizing the gapless promotion, for example, a lens shape is transferred to an organic film provided as an intermediate film once, and the lens shape is further transferred from the organic film to an inorganic film. The resist etchback method, for example, is described in Japanese Patent Laid-Open No. 2008-9079.

In the etchbackless method described in (2), for example, for the purpose of preventing the fusion, a gray mask is used. The etchbackless method, for example, is described in Japanese Patent Laid-Open No. 2007-316153.

In the nanoimprint method described in (3), for example, a microlens model is pressed against a microlens formation film to form the microlens. The nanoimprint method, for example, is described in Japanese Patent Laid-Open No. 2009-199045.

In recent years, along with the scale down of the pixels in the solid-state image pickup device, a processing precision has been required for not only the microlens, but also a color filter (CF). In the processing for the CF, three color materials composed of photosensitive resins composing the CFs, for example, are patterned through both of exposure processing and development processing in order of Red (R), Green (G), and Blue (B). However, it is feared that color mixture characteristics of the solid-state image pickup device become worse due to superposition misalignment for each color corresponding to the processing precision.

A technique with which for the purpose of making it possible to readily specify an end point of planarizing processing which is carried out when CFs in and after a second level color are formed after a CF of a first level color has been formed, a layer containing therein a silicon compound is formed on the CF of the first level color, and the CFs of the second level color and the third level color are formed with this layer as either a stopper of etchback or an end point of Chemical Mechanical Polishing (CMP) is proposed as a method of manufacturing CFs. This technique, for example, is described in Japanese Patent Laid-Open No. 2009-244710.

In addition, a technique is proposed with which for the purpose of improving the color mixture characteristics of the solid-state image pickup device, a light blocking body is provided in a boundary between each adjacent two CFs. This technique, for example, is described in Japanese Patent Laid-Open Nos. 2010-239076, 2010-134353, and Hei 10-163462.

In addition thereto, a technique is proposed with which irregularities are formed in bases of the CFs, thereby adjusting a thickness of each of the CFs. This technique, for example, is described in Japanese Patent Laid-Open Nos. 2006-269533 and 2006-222291.

### SUMMARY

In the case of the resist etchback method described in (1), an overall etching amount is doubled, which results in a damage due to plasma and an ultraviolet light being feared. In addition, the etching amount is increased, which results in dust and uniformity within a wafer surface becoming worse.

In the case of the etchbackless method described in (2), a special and expensive gray mask is used.

Also, in the nanoimprint method described in (3), the inorganic resist film made of a tungsten oxide or the like is subjected to the exposure processing while a radiation intensity of an exposure light is controlled, thereby manufacturing the microlens model. Therefore, the manufacture of the microlens model is complicated, and thus a lot of trouble and time are taken.

Therefore, in any of those methods described in (1) to (3), the manufacturing cost becomes high.

Moreover, in the case as well of the CF manufacturing method, with the technique described in Japanese Patent Laid-Open No. 2009-244710, the CFs of the three level colors are not formed in the self-alignment manner, and thus it cannot be said that the processing precision is high.

In addition, in the case of the techniques described in Japanese Patent Laid-Open Nos. 2010-239076, 2010-134353, and Hei 10-163462, after the light blocking body has been formed, each of the CF materials are filled therein. In this case, however, there is a limit to the processing precision, and thus there is the possibility that it may be impossible to actually improve the color mixture characteristics.

Moreover, in the case of the technique described in Japanese Patent Laid-Open No. 2006-269533, the irregularities of the bases of the CFs are etched by using a resist mask and finally, the upper surfaces of the CFs are polished to become flush with one another. However, when it may be impossible to suitably carry out the polishing control corresponding to differences among the compositions of the CFs, the desired spectral characteristics are not obtained with respect to the CFs and thus it is feared that both of the color reproducibility and the sensitivity characteristics are deteriorated.

In addition, the technique described in Japanese Patent Laid-Open No. 2006-222291 is such that after the first level color CF has been formed by utilizing the dry etching method, the second level color and third level color CFs are both formed by utilizing the photolithography method. In this case, however, Japanese Patent Laid-Open No. 2006-222291 discloses that while the first level color CF is formed, the organic film formed as the base of the first level color CF is etched partway. In this case, when the etching precision is poor, there is the possibility that the dispersion is caused in the thicknesses of the second level color and third level color CFs and thus the color reproducibility and the sensitivity characteristics are both deteriorated. In addition, although it is expected that for the purpose of stopping the etching in the middle of the organic film, the thickness of the CF is increased, in this case, it is feared that the light condensing characteristics of the solid-state image pickup device becomes worse and thus the sensitivity characteristics and the shading characteristics are both deteriorated.

The present disclosure has been made in order to solve the problems described above, and it is therefore desirable to provide a method of manufacturing a solid-state image pickup element with which characteristics deterioration of the solid-state image pickup element are suppressed and the solid-state image pickup element can be readily manufactured while a non-effective area of a lens is reduced and thus processing precision is maintained.

Also, it is desirable to provide the solid-state image pickup element which is manufactured by the manufacturing method, an image pickup device including the solid-state image pickup element, and an electronic apparatus including the image pickup device.

In order to attain the desire described above, according to a mode of the present disclosure, there is provided a method of manufacturing a solid-state image pickup element having a lens provided above a light receiving portion, the manufacturing method including: forming a lens base material layer composing the lens; forming an intermediate film having a thermal expansion coefficient larger than that of a resist on the lens base material layer; forming the resist in contact with the intermediate film; forming the resist into a lens shape by thermal reflow; and transferring the lens shape of the resist to the lens base material layer by etching, thereby forming the lens.

According to another mode of the present disclosure, there is provided a method of manufacturing a solid-state image pickup element having a lens provided above a light receiving portion, the manufacturing method including: forming an intermediate film having a thermal expansion coefficient larger than that of a resist; forming the resist in contact with the intermediate film; and forming the resist into a lens shape by thermal reflow, thereby forming the lens composed of the resist.

According to still another mode of the present disclosure, there is provided a solid-state image pickup element including: a light receiving portion formed in a semiconductor substrate; an intermediate film having a thermal exposure coefficient larger than that of a resist and formed above the light receiving portion; and a lens composed of the resist and formed in contact with the intermediate film.

According to yet another mode of the present disclosure, there is provided an image pickup device including: an optical system; a solid-state image pickup element having a light receiving portion formed in a semiconductor substrate, an intermediate film having a thermal expansion coefficient larger than that of a resist and formed above the light receiving portion, and a lens composed of the resist and formed in contact with the intermediate film; and a signal processing circuit processing an output signal from the solid-state image pickup element.

According to a further mode of the present disclosure, there is provided a solid-state image pickup element including: a pixel area having an effective pixel area, and a non-effective pixel area other than the effective pixel area, in which each of pixels within the effective pixel area includes a cover film made of one of an inorganic material or an organic material, and a microlens made of the other of the inorganic material or the organic material on a color filter; and the color film is formed in the non-effective pixel area as well.

According to a still further mode of the present disclosure, there is provided a method of manufacturing a solid-state image pickup element including: of a pixel area having an effective pixel area and a non-effective pixel area other than the effective pixel area, after forming a color filter in each of pixels within the effective pixel area, forming a cover film made of one of an inorganic material or an organic material in the effective pixel area and the non-effective pixel area; forming a lens material layer made of the other of the inorganic material or the organic material as a material of a microlens on the cover film in the effective pixel area; and detecting exposure of the cover film in etching with which the lens material layer is formed into a lens shape, thereby ending the etching.

According to a yet further mode of the present disclosure, there is provided an electronic apparatus including: a pixel area having an effective pixel area and a non-effective pixel area other than the effective pixel area, in which each of pixels within the effective pixel area includes a cover film made of one of an inorganic material or an organic material, and a microlens made of the other of the inorganic material or the organic material on a color film; and the cover film is formed in the non-effective pixel area as well.

According to an even further mode of the present disclosure, there is provided a solid-state image pickup device including a color filter including: a filter having a predetermined color component corresponding to a predetermined pixel of plural pixels formed in a lattice; filters having other color components corresponding to other pixels, respectively, and formed in each of areas other than areas in each of which the filter having the predetermined color component is formed; and a light attenuating film attenuating a light transmittance and formed in a boundary between the filter having the predetermined color component and the filters having other color components, in which the areas each of which the filter having the predetermined color component is formed are linked to one another in at least parts thereof; and a bottom surface of each of the filters having other color components and the light attenuating film is lower than that of the filter having the predetermined color filter.

According to an even further mode of the present disclosure, there is provided a method of manufacturing a solid-state image pickup device including: a filter having a predetermined color component corresponding to a predetermined pixel of plural pixels formed in a lattice; filters having other color components corresponding to other pixels, respectively, and formed in each of areas other than areas in each of which the filter having the predetermined color component is formed; and a light attenuating film attenuating a light transmittance and formed in a boundary between the filter having the predetermined color component, and the filters having other color components, in which the areas each of which the filter having the predetermined color component is formed are linked to one another in at least parts thereof; and a bottom surface of each of the filters having other color components and the light attenuating film is lower than that of the filter having the predetermined color filter. The manufacturing method includes: depositing a material for the filter having the predetermined color component on an organic film formed on an inorganic film; forming a photo resist in the areas in each of which the filter having the predetermined color component is formed, and carrying out etching processing for the material for the filter having the predetermined color component; forming the light attenuating film in the filter having the predetermined color component for which the etching processing is carried out; carrying out etching processing for the filter having the predetermined color component in which the light attenuating film is formed; and applying materials for the filters having other color components, respectively.

As set forth hereinabove, according to the present disclosure, since the non-effective area of the lenses can be reduced, the loss due to the non-effective area can be reduced and thus the sensitivity of the solid-state image pickup element can be enhanced.

Since the non-effective area between the adjacent lenses can be reduced by only forming the intermediate film having the thermal expansion coefficient which is larger than that of the resist as the base of the resist, the solid-state image pickup element can be simply, inexpensively manufactured.

In addition, according to one mode of the present disclosure, the deterioration of the characteristics of the solid-state image pickup device can be suppressed while the processing precision is maintained.

### BRIEF DESCRIPTION OF THE DRAWINGS

FIG. 1 is a block diagram, partly in circuit, showing an entire schematic configuration of a solid-state image pickup element to which embodiments of the present disclosure is applied;

FIG. 2 is a cross sectional view showing a structure of a main portion of the solid-state image pickup element according to a first embodiment of the present disclosure;

FIGS. 3A to 3F are respectively cross sectional views showing manufacturing processes for manufacturing the solid-state image pickup element according to the first embodiment of the present disclosure;

FIG. 4 is a cross sectional view showing a structure of a main portion of a solid-state image pickup element according to a second embodiment of the present disclosure;

FIGS. 5A to 5E are respectively cross sectional views showing manufacturing processes for manufacturing the solid-state image pickup element according to the second embodiment of the present disclosure;

FIGS. 6A to 6F are respectively cross sectional views showing manufacturing processes for manufacturing a solid-state image pickup element according to a third embodiment of the present disclosure;

FIG. 7 is a top plan view showing a structure of a color filter of a solid-state image pickup element according to a modification of the first embodiment of the present disclosure;

FIGS. 8A and 8B are respectively a cross sectional view taken on line X-X′ of FIG. 7, and a cross sectional view taken on line Y-Y′ of FIG. 7;

FIG. 9 is a cross sectional view showing a structure of a main portion of a solid-state image pickup element according to a fourth embodiment of the present disclosure;

FIGS. 10A to 10D are respectively cross sectional views showing manufacturing processes for manufacturing the solid-state image pickup element according to the fourth embodiment of the present disclosure;

FIGS. 11A and 11B are respectively views explaining a difference in a resist in a phase of thermal reflow due to a magnitude relationship in thermal expansion coefficient between the resist and a base film;

FIGS. 12A and 12B are respectively cross sectional views explaining a difference of change in a cross-sectional shape of the resist in the phase of the thermal reflow due to the magnitude relationship in thermal expansion coefficient between the resist and the base film;

FIG. 13 is a diagram explaining a difference in slip amount due to a difference in base material;

FIG. 14 is a diagram explaining a relationship between a crosslink density and a state after post exposure bake in a base;

FIG. 15 is a graph explaining a relationship between a residual rate after exposure bake, and a slip amount;

FIG. 16 is a graph explaining a relationship between a length of a non-effective area, and a sensitivity rate in a microlens;

FIGS. 17A and 17B are respectively a graph explaining a relationship between post exposure bake time and a film thickness change rate, and a graph explaining a relationship between the post exposure bake time and a reaction rate;

FIG. 18 is a cross sectional view showing a structure of a pixel in a solid-state image pickup element according to a fifth embodiment of the present disclosure;

FIG. 19 is a top plan view showing a structure of dispositions of color filters included in the solid-state image pickup element according to the fifth embodiment of the present disclosure;

FIGS. 20A and 20B are respectively cross sectional views each showing a structure of the color filter included in the solid-state image pickup element according to the fifth embodiment of the present disclosure;

FIG. 21 is a cross sectional view explaining a method of forming microlenses included in the solid-state image pickup element according to the fifth embodiment of the present disclosure;

FIG. 22 is a cross sectional view explaining a method of forming microlenses included in the solid-state image pickup element according to a sixth embodiment of the present disclosure;

FIG. 23 is a cross sectional view explaining a method of forming microlenses in a solid-state image pickup element according to a seventh embodiment of the present disclosure;

FIG. 24 is a cross sectional view explaining a method of forming microlenses in a solid-state image pickup element according to an eighth embodiment of the present disclosure;

FIGS. 25A and 25B are respectively a top plan view and a cross sectional view of color filters included in a solid-state image pickup device according to a ninth embodiment of the present disclosure;

FIGS. 26A and 26B are respectively a top plan view showing a structure of the solid-state image pickup device including the color filters, according to the ninth embodiment of the present disclosure, and a cross sectional view taken on line b-b′ of FIG. 26A;

FIGS. 27A and 27B are respectively cross sectional views explaining an incident light made incident to a light receiving area of the solid-state image pickup device of the ninth embodiment;

FIGS. 28A and 28B are respectively views explaining a bottom surface of a light attenuating film;

FIG. 29 is a flow chart explaining processing for forming the color filters shown in FIG. 25;

FIGS. 30A to 30K are respectively cross sectional views explaining the processing for forming the color filters shown in FIG. 25;

FIGS. 31A and 31B are respectively cross sectional views explaining adjustment of an etching amount;

FIGS. 32A and 32B are respectively cross sectional views explaining another structure of the light attenuating film;

FIGS. 33A and 33B are respectively cross sectional views showing a structure of color filters included in a solid-state image pickup device according to a first modification of the ninth embodiment of the present disclosure;

FIG. 34 is a flow chart explaining processing for forming the color filters shown in FIGS. 33A and 33B;

FIGS. 35A to 35K are respectively cross sectional views explaining the processing for forming the color filters shown in FIGS. 33A and 33B;

FIG. 36 is a top plan view showing color filters having another disposition in a solid-state image pickup device according to a second modification of the ninth embodiment of the present disclosure;

FIG. 37 is a top plan view showing a color filter having still another disposition in a solid-state image pickup device according to a third modification of the ninth embodiment of the present disclosure; and

FIG. 38 is a block diagram showing a configuration of an image pickup apparatus as an electronic apparatus according to a tenth embodiment of the present disclosure.

### DETAILED DESCRIPTION OF THE PREFERRED EMBODIMENTS

### 1. Outline of the Present Disclosure

Firstly, prior to giving of a concrete description of embodiments, an outline of the present disclosure will be described below.

The present disclosure aims at providing a method of manufacturing a solid-state image pickup element with which a non-effective area of lenses (microlens) provided above a light receiving portion can be reduced, and which can be simply, inexpensively manufactured.

With a manufacturing method, of transferring a lens shape of a resist to a lens base material layer by utilizing an etchback method, which has been proposed in the past, even when the same resist is used, a shape of a resist is changed depending on a material and a state of a base of the resist and thus the shape of the lens is difficult to control.

Also, the inventor of the present disclosure has carried out the study and as a result, it has been found out that the change in the shape of the lens described above is due to a difference in thermal expansion coefficient between a lens formation material and a base film.

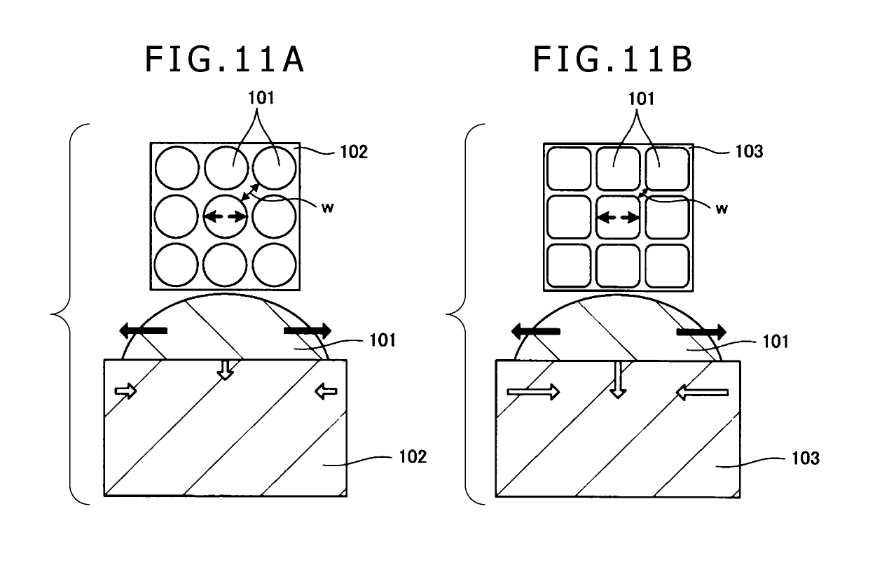

Here, FIGS. 11A and 11B show a difference in change of a resist in a phase of thermal reflow due to a magnitude relationship in thermal expansion coefficient between the resist and a base film. Upper-side parts of FIGS. 11A and 11B are respectively top plan views each showing a disposition of three pixels×three pixels, and lower-side parts of FIGS. 11A and 11B are respectively cross sectional views each showing a structure of one pixel.

When a relationship of a thermal expansion coefficient of a resist>a thermal expansion coefficient of a base film holds true by using the base film 102 having a small thermal exposure coefficient, as shown in the lower-side part of FIG. 11A, a force (indicated by white arrows) by which a volume change is caused due to heat of the base film 102 is smaller than a force (indicated by black arrows) by which the resist 101 is reflowed. For this reason, a deterrent force applied to a direction in which the resist 101 is attempting to be reflowed is small and thus a slip amount of resist 101 becomes large. In such a case, as shown in the upper-side part of FIG. 11A, the resist 101 largely spreads in all of directions due to the thermal reflow and thus a planar shape of the resist 101 becomes close to a circle. Also, since the slip amount of resist 101 is large, it is necessary to set a wide gap between each adjacent two resists 101 before the thermal reflow. As a result, a width, w, of a non-effective area in an oblique direction becomes large.

On the other hand, when a relationship of the thermal expansion coefficient of the resist<the thermal expansion coefficient of the base film holds true by using the base film 103 having a large thermal expansion coefficient, as shown in the lower-side part of FIG. 11B, a force (indicated by white arrows) by which a volume change is caused due to heat of the base film 103 becomes approximately equal to a force (indicated by black arrows) by which the resist 101 is ref lowed. For this reason, a deterrent force applied to a direction in which the resist 101 is attempting to be reflowed becomes large and thus a slip amount of resist 101 becomes small. In such a case, as shown in the upper-side part of FIG. 11B, the spreading of the resist 101 due to the thermal reflow is small. Therefore, the shape of the resist 101 before the thermal reflow is approximately maintained. Also, since the slip amount of resist 101 is small, it becomes possible to narrow the gap between each adjacent two resists 101 before the thermal reflow. As a result, the width, w, of the non-effective area in the oblique direction becomes small.

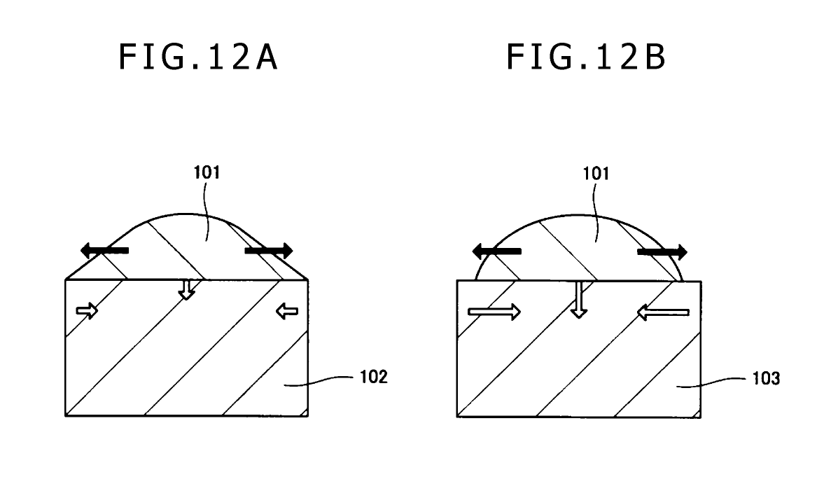

In addition, FIGS. 12A and 12B show a difference in change of a cross-sectional shape of the resist in the phase of the reflow due to the magnitude relationship in thermal expansion coefficient between the resist and the base film. Each of FIGS. 12A and 12B shows a cross sectional view of one pixel. In FIGS. 12A and 12B, a white arrow and a black arrow show the same means as those in FIGS. 11A and 11B.

When the relationship of the thermal expansion coefficient of the resist>the thermal expansion coefficient of the base film holds true, as shown in FIG. 12A, a force (indicated by the white arrows) by which the volume change is caused due to the heat of the base film 102 is smaller than a force (indicated by the black arrows) by which the resist 101 is ref lowed. For this reason, the deterrent force applied to the direction in which the resist 101 is attempting to be reflowed is small and thus a slip amount of resist 101 becomes large. In such a case, the resist 101 is slipped to spread in a horizontal direction, whereby the cross-sectional shape of the resist 101 is destroyed to become easy to become an aspherical shape as shown in FIG. 12A. In this case, even when the lens shape of the resist 101 is transferred to a lens formation material, the lens comes to have the aspherical shape and thus the shifting of a light condensing point is generated.

On the other hand, when the relationship of the thermal expansion coefficient of the resist<the thermal expansion coefficient of the base film holds true, as shown in FIG. 12B, the force (indicated by the white arrows) by which the volume change is caused due to the heat of the base film 102 becomes approximately equal to the force (indicated by the black arrows) by which the resist 101 is reflowed. For this reason, the deterrent force applied to the direction in which the resist 101 is attempting to be reflowed is large and thus a slip amount of resist 101 becomes small. In such a case, as shown in FIG. 12B, the cross-sectional shape of the resist 101 is easy to hold the spherical shape. In this case, even when the lens shape of the resist 101 is transferred to the lens formation material, since the lens has the spherical shape, the light condensing point can be suitably set.

Next, actually, various kinds of materials were used as the material of the base film, and a state of patterning after the development processing, and a state after the thermal reflow is carried out by post exposure bake were checked with respect to the same resist material. In addition, the slip amount of resist before and after the reflow was measured.

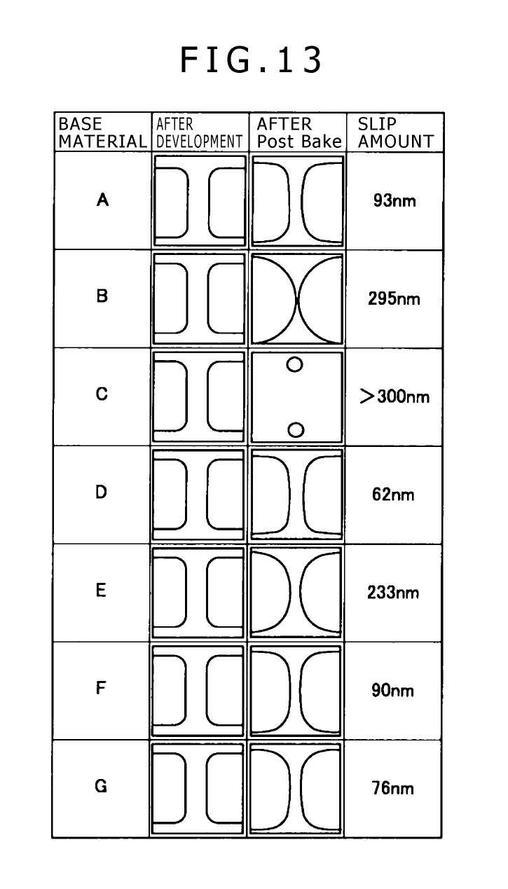

Results of checking seven kinds of base materials: A to G are shown in FIG. 13.

As can be seen from FIG. 13, even when the same resist material is used, a slip amount of resist is largely changed depending on the base material. In the case of the base material C, a slip amount of resist is too large and thus the resists of the adjacent pixels are linked to each other.

In addition, when the material whose thermal expansion coefficient is changed due to a crosslink density is used in the base film, the change of the resist shape due to the reflow differs depending on a state of the crosslink of the base film and thus the control is difficult to carry out.

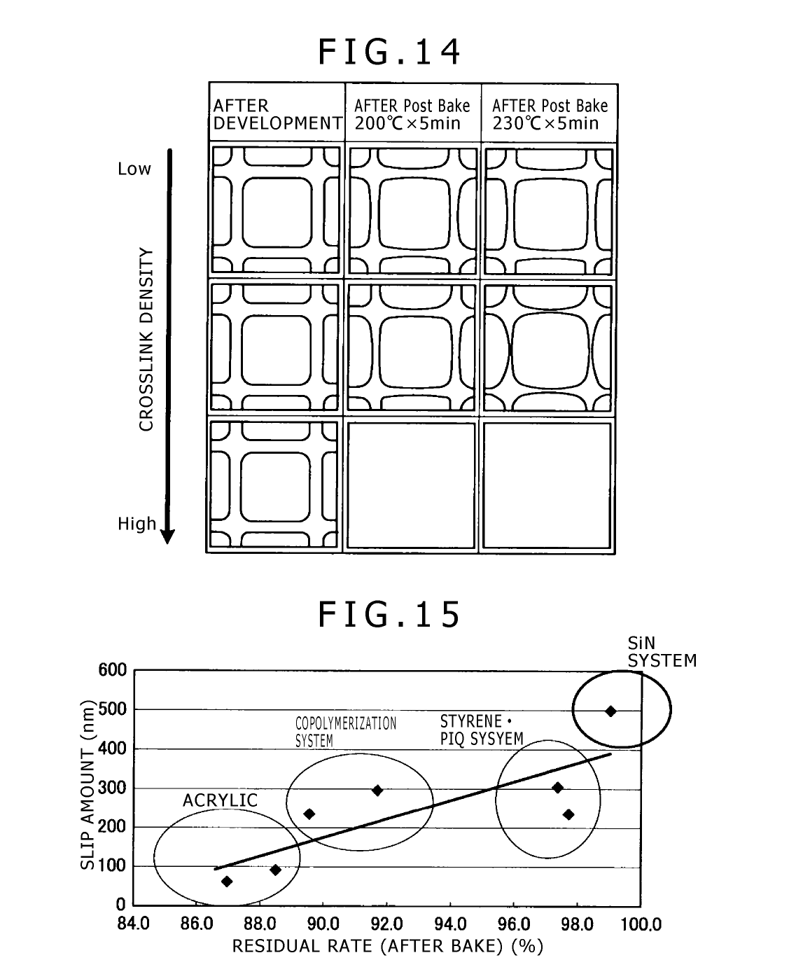

Here, three different kinds of crosslink densities were set with respect to the same resin, each of the same resins having the three crosslink densities was used in the base film, and the resist was formed into a development pattern for a lens on the base material. Also, the shapes of the resists were compared with one another with respect to a state after the development, the case where the post exposure bake was carried out at 200° C. for five minutes, and a state in which the post exposure bake was carried out at 230° C. for five minutes. The resulting planar shapes of the respective resists are shown in FIG. 14.

As can be seen from FIG. 14, when the crosslink density of the resin of the base film is made large, a slip amount of resist becomes large and thus the resists of the adjacent pixels are linked to one another. On the other hand, when the crosslink density of the resin of the base film is made small, the planar shape of the resist after the development becomes easy to maintain.

Also, when the crosslink density of the resin of the base film is made middle, it is understood that a slip amount of resist is increased when the temperature of the post exposure bake is made to rise from 200° C. to 230° C. On the other hand, when the crosslink density of the resin of the base film is made small, it is understood that the shape of the resist is maintained even when the temperature of the post exposure bake is made to rise up to 230° C.

It is thought that the reason for those results is because the thermal expansion coefficient becomes small when the crosslink density of the resin of the base material is made large, and the thermal expansion coefficient becomes large when the crosslink density of the resin of the base material is made small.

As can be understood from the above results, the base material is selected in such a way that the thermal expansion coefficient of the base film becomes large, whereby a slip amount of resist in the phase of the reflow can be made small and thus the spreading and the change of the shape in the resist can be suppressed.

Next, some materials were selected for the base film, and the resist was formed on each of the base films made of the respective materials thus selected, and the reflow was carried out, thereby forming the resist into the lens shape. At this time, a residual rate at which the base film is left after the exposure bake in the phase of the reflow, and a slip amount of resist due to the reflow were both measured.

The measurement results are shown in FIG. 15. In FIG. 15, an axis of abscissa represents the residual rate after the exposure bake for the base film, and an axis of ordinate represents a slip amount of resist. In addition, with regard to the materials for the base film, the results in the materials belonging to the same system are surrounded in a lump by a large circle.

As can be seen from FIG. 15, the resist is slipped, that is, the width of the non-effective area becomes large as the residual rate after the exposure bake is larger, that is, a cure degree is larger and the thermal expansion coefficient is smaller.

With regard to the materials of the systems, the magnitude of the residual rate follow the ascending order of an acrylic system, a copolymerization system, a styrene.polyisoindolo quinazoline dione (PIQ) system, and a SiN system.

A measurement of the thermal expansion coefficient of the material is not simply carried out. Thus, by utilizing this result, the material exhibiting the large residual rate after the exposure bake, that is, the large shrinkage rate is simply selected, thereby making it possible to increase the thermal exposure coefficient of the base film.

From the results shown in FIG. 15, using the acrylic system in the base film of the resist results in an ideal combination. However, since the etching rate of the acrylic system is difficult to control when the lens shape is transferred to the lens formation material by utilizing the etching method, it is expected to use the copolymerization system.

Here, the case where, for example, after an acrylic or styrene film (thermal expansion coefficient: 5.0 to 8.35/° C.) was disposed as the base film on a SiN film (thermal expansion coefficient: 3.0×10⁻⁶/° C.), a resist was formed on the acrylic or styrene film, and the case where a resist film was directly formed on the SiN film were compared with each other.

It was found out that in the case where the base film was formed on the SiN film, the width of the non-effective area in the oblique direction after the reflow is reduced as compared with the case where the resist is directly formed on the SiN film. For example, when a cell size is set to 1.0 μm, the width of the non-effective area in the oblique direction is reduced from 400 nm to 320 nm by 20%.

In addition, the simulations were carried out with regard to various cell sizes, and a relationship between the width of the non-effective area, and an effective area rate (a value which is normalized as 100 when a non-effective area is zero) of the lens was checked. As a result, it was found out that when the cell size is set to 1.0 μm, as described above, the width of the non-effective area in the oblique direction is reduced from 400 nm to 320 nm by 200, whereby the effective area rate is increased by 7%. Since the effective area rate is proportional to the sensitivity, it is understood that the sensitivity is also increased by 7%.

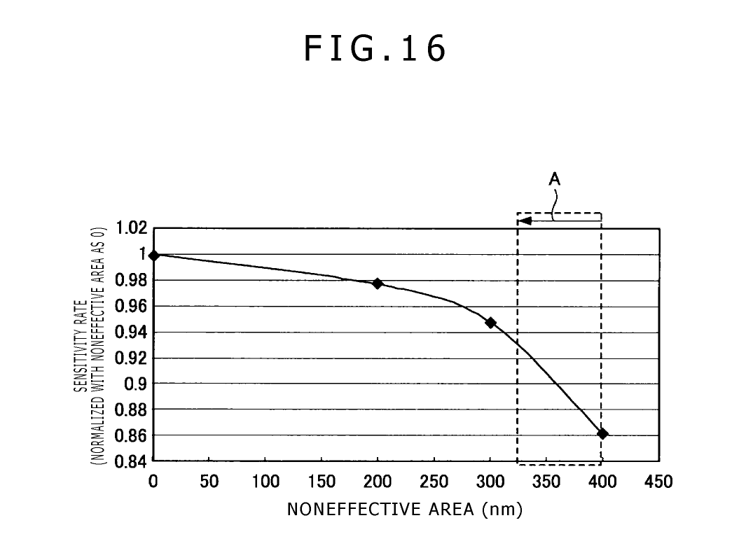

In addition thereto, with respect to the case where the cell size was set to 1.6 μm in a back surface radiation type structure, the simulations were carried out while the width of the non-effective area was changed, thereby obtaining the sensitivities. The results are shown in FIG. 16. In FIG. 16, an axis of abscissa represents the width (nm) of the non-effective area, and an axis of ordinate represents the sensitivity rate which is normalized based on the case where the non-effective area is zero.

As indicated by an arrow A in FIG. 16, it is understood that when the width of the non-effective area is reduced from 400 nm to 320 nm by 200, the sensitivity rate is improved from 86% up to 93% by seven points.

By taking the results described above as well into consideration, the present disclosure adopts the following constitutions.

One method of manufacturing a solid-state image pickup element of the present disclosure (first manufacturing method) includes a process for forming a lens base material layer composing a lens, and a process for forming an intermediate film having a thermal expansion coefficient larger than that of a resist on the lens base material layer.

In addition, the first manufacturing method includes a process for forming a resist in contact with the intermediate film, a process for forming the resist into a lens shape by thermal reflow, and a process for transferring the lens shape of the resist to the lens base material layer by etching, thereby forming a lens.

In addition, the other method of manufacturing a solid-state image pickup element of the present disclosure (second manufacturing method) includes a process for forming an intermediate film having a thermal expansion coefficient larger than that of a resist, and a process for forming a resist in contact with the intermediate film.

In addition thereto, the second manufacturing method includes a process for forming the resist into a lens shape by thermal reflow, thereby forming a lens composed of the resist.

A solid-state image pickup element of the present disclosure has a structure in which an intermediate film having a thermal expansion coefficient larger than that of a resist is formed above a light receiving portion formed on a semiconductor base, and a lens composed of a resist is formed in contact with the intermediate film. That is to say, the solid-state image pickup element of the present disclosure has the structure manufactured by utilizing the second manufacturing method described above.

An image pickup device of the present disclosure has a configuration of including the solid-state image pickup element of the present disclosure described above, an optical system, and a signal processing circuit for processing an output signal from the solid-state image pickup element.

According to the first manufacturing method and second manufacturing method described above, the resist is formed in contact with the intermediate film having the thermal expansion coefficient larger than that of the resist and thereafter, the resist is formed into the lens shape by the thermal reflow. As a result, by the formation of the intermediate film having the thermal expansion coefficient larger than that of the resist, the force by which the resist is attempting to spread in the phase of the thermal reflow can be suppressed, thereby reducing the slip amount of resist. Therefore, even when the interval between the adjacent resists is narrowed, the adjacent resists are prevented from being linked to each other. For this reason, the non-effective area of the lens can be reduced by narrowing the interval between the adjacent resists.

Also, the reduction of the non-effective area of the lens results in that the sensitivity of the solid-state image pickup element can be enhanced by reducing the loss due to the non-effective area.

In addition, the non-effective area between the adjacent lenses can be reduced by only forming, as a base for the resist, the intermediate film having the thermal expansion coefficient larger than that of the resist. As a result, the solid-state image pickup element can be simply, inexpensively manufactured.

In the case of the technique described in Japanese Patent Laid-Open No. 2008-9079, since the lens shape is transferred to the intermediate film, the material of the intermediate film is selected in consideration of the etching rate. In addition, the thickness of the intermediate film needs to be above some extent so as to correspond to the lens shape to be transferred. Also, since the intermediate film is formed thickly, an etching amount during the transferring is increased and thus the damage due to the ultraviolet light and the plasma becomes large.

On the other hand, in the present disclosure, the intermediate film is not used to transfer the lens shape to the intermediate film, but the force by which the resist is attempting to spread in the phase of the thermal reflow is suppressed by utilizing the difference in the thermal expansion coefficient between the resist and the intermediate film. As a result, the non-effective area of the lens is reduced, whereby the sensitivity of the solid-state image pickup element can be enhanced and thus the color mixture can be suppressed.

In the present disclosure, since the lens shape is not transferred to the intermediate film, even when the intermediate film is thinly formed irrespective of the thickness of the lens, the effect that the force by which the resist is attempting to spread in the phase of the thermal reflow is suppressed is sufficiently obtained. Therefore, the intermediate film can be formed in the form of a thin film.

The intermediate film is formed in the form of the thin film, whereby as compared with the case where the lens shape is transferred to the intermediate film as with the technique described in Japanese Patent Laid-Open No. 2008-9079, the entire thickness which is subjected to the etching processing can be reduced and thus a Process Induces Damage (PID) such as the damage due to the ultraviolet light and the plasma can be suppressed.

In addition, in the present disclosure, there is not a restriction to the material of the intermediate film due to the etching rate and thus the degree of freedom of the material selection is increased. Since all it takes is that the intermediate film is formed in the form of the thin film, for example, such a material as to absorb an i-line is selected, so that the intermediate film can also be made to operate as an antireflection film.

In the first manufacturing method and second manufacturing method described above, in the solid-state image pickup element of the present disclosure, the thickness of the intermediate film is preferably set to 0.3 μm or less and is more preferably set to 0.1 μm or less. In particular, when the thickness of the intermediate film is set to 0.1 μm or less, the intermediate film becomes the thin film such that the reflection from an interface can be ignored for a light having the shortest wavelength of about 400 nm of a visible light, which does not cause the light condensing loss.

In the first manufacturing method in which the lens shape of the resist is transferred to the lens base material layer, and the resulting lens base material layer is then etched, the thickness of the intermediate film is sufficiently thinned to 0.3 μm or less, whereby a difference in the etching rate is not generated, and an influence on time required for the etching process is also small.

In the second manufacturing method and the solid-state image pickup element of the present disclosure in each of which the resist is directly used as the lens, the thickness of the intermediate film is sufficiently thinned to 0.3 μm or less, whereby an influence, on the light condensing, such as the reflection from the interface of the intermediate film can be reduced.

It is noted that although depending on the material and film depositing method of the intermediate film, a lower limit of the thickness of the intermediate film is set to a minimum thickness with which the uniform film can be formed over the entire pixel portion of the solid-state image pickup element.

A material having a thermal expansion coefficient larger than that of the material of the resist is used as the material of the intermediate film.

For example, when the material of the resist is a novolac resin, an acrylic resin or the like having a thermal expansion coefficient larger than that of the novolac resin is used as the material of the intermediate film.

In addition, when the resin material, as shown in FIG. 14, whose thermal expansion coefficient is changed depending on the crosslink density is used as the material of the intermediate film, the crosslink density is reduced to increase the thermal expansion coefficient. For example, if a curing temperature after deposition of the intermediate film is lowered or a curing time is shortened, then, the crosslink density can be reduced. However, when the resist is applied, the intermediate film is cured to the degree that the intermediate film is not changed by a solvent of the resist or is not mixed with the resist.

Here, specimens were manufactured in such a way that the resist was formed on the intermediate film made of a specific material, and a temperature and time of the post exposure bake of the thermal reflow were changed. The temperature of the post exposure bake was set to 200° C. and 230° C.

With respect to the specimens, a change in a thickness and a reaction rate of the intermediate film when a film was dipped in an MMP (methyl 3-methoxypropionate) thinner were checked. The reaction rate of the intermediate film was obtained from the degree of decrease of a peak height of an infrared spectrum when an FT-IR (Fourier transform infrared) measurement of the specimen was carried out.

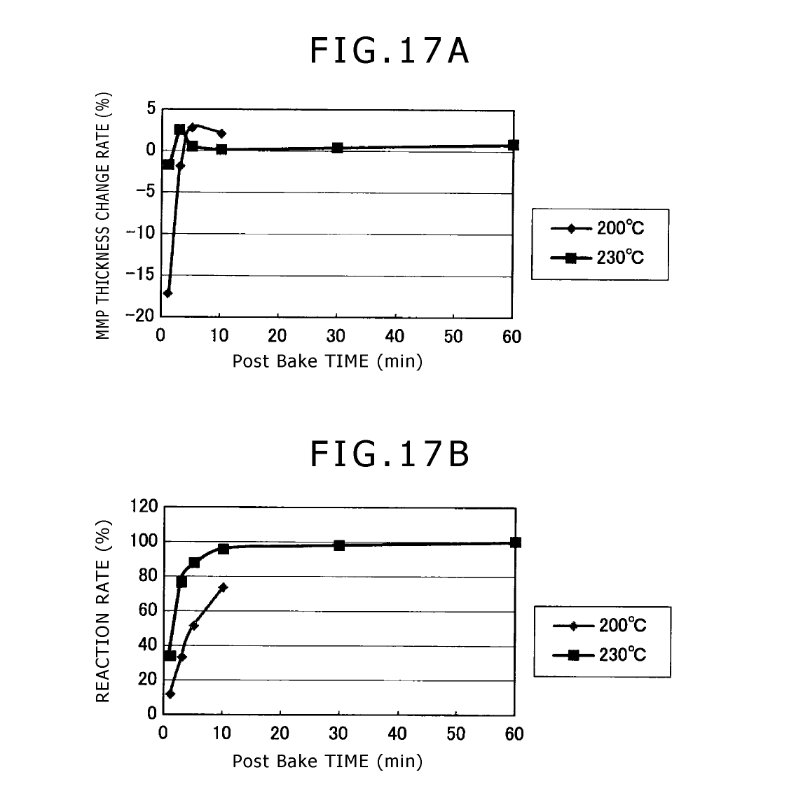

The measurement results of the specimens are shown in FIGS. 17A and 17B, respectively. FIG. 17A shows a relationship between the post exposure bake time and the change rate of the thickness due to the MMP thinner. Also, FIG. 17B shows a relationship between the time of the post exposure bake time, and the reaction rate.

From the results shown in FIGS. 17A and 17B, it is understood that when the temperature of the post exposure bake was set to 230° C., the reaction almost ends for about ten minutes and thus the change in the thickness becomes small. On the other hand, it is understood that when the temperature of the post exposure bake was set to 200° C., the reaction rate is about 73% for ten minutes and thus the thickness is changed by about 20 due to the solvent.

Therefore, the temperature of the post exposure bake is set to 200° C., whereby the curing degree is reduced, thereby making it possible to form the intermediate film having the large thermal expansion coefficient.

In addition, from the results shown in FIGS. 17A and 17B, it is expected that when the temperature of the post exposure bake is set to 200° C., if the post exposure bake is carried out for about three minutes or more, then, a solvent resistance is sufficiently obtained and thus it is possible to prevent the mixing when the resist is applied by utilizing a spin coating method.

### 2. First Embodiment

### Solid-State Image Pickup Element and Method of Manufacturing the Same

Subsequently, a concrete embodiment (first embodiment) of the present disclosure will be described.

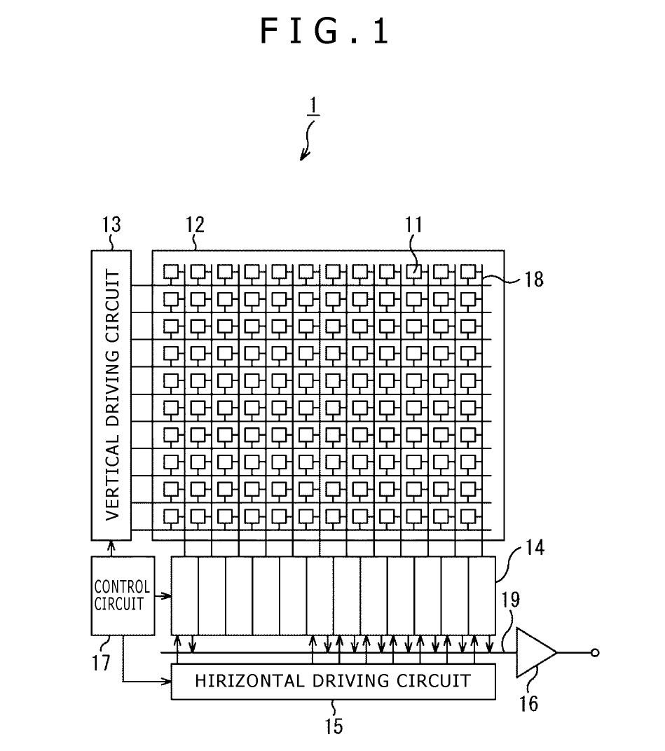

FIG. 1 is a top plan view showing a schematic configuration of a solid-state image pickup element according to the first embodiment of the present disclosure.

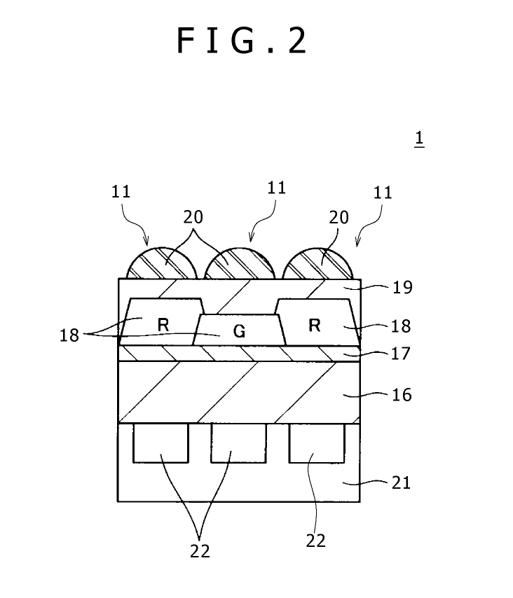

Also, FIG. 2 is a cross sectional view showing a structure of a main portion of the solid-state image pickup element according to the first embodiment of the present disclosure.

In the first embodiment, the present disclosure is applied to a CMOS (complementary metal-oxide semiconductor) type solid-state image pickup element.

### [Entire Configuration of Solid-State Image Pickup Element]

FIG. 1 is a schematic view showing an entire configuration of the solid-state image pickup element of the first embodiment to which the present disclosure is applied. A solid-state image pickup element 1 shown in FIG. 1, for example, is a back surface radiation type CMOS solid-state image pickup element.

The solid-state image pickup element 1 includes a pixel area 12 including pixels 11 which are two-dimensionally disposed, a vertical driving circuit 13, column signal processing circuits 14, a horizontal driving circuit 15, an output circuit 16, a control circuit 17, and the like.

The pixel 11 is composed of a photodiode as a photoelectric conversion element, and plural pixel transistors. The plural pixel transistors composing the pixel 11 may be four pixel transistors composed of a transfer transistor, a reset transistor, a selection transistor, and an amplification transistor, or may be three pixel transistors except for the selection transistor.

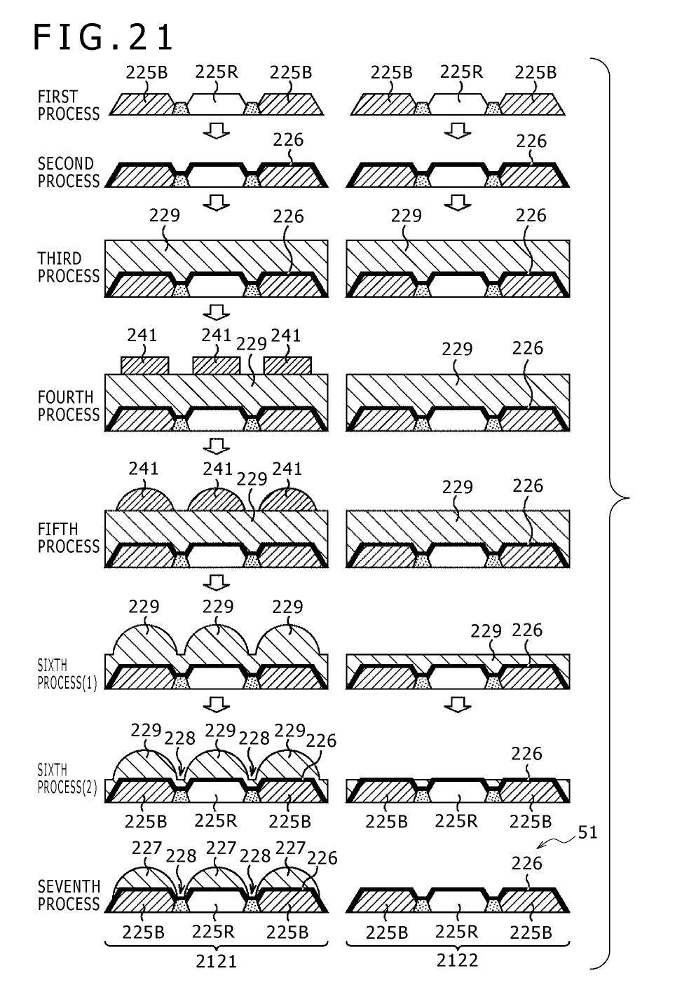

Plural pixels 11 are regularly disposed in a two-dimensional matrix in the pixel area 12. The pixel area 12 is composed of an effective pixel area 2121 (refer to FIG. 21), and a non-effective pixel area 2122 (refer to FIG. 21) other than the effective pixel area 2121. In this case, in the effective pixel area 2121, signal electric charges into which a light actually received is photoelectrically converted are amplified to output the resulting electric signal to the column signal processing circuit 14. An Optical Black (OPB) area for output of a signal corresponding to optical black becoming a reference of a black level, and the like are included in the non-effective pixel area 2122. The non-effective pixel area 2122 is normally formed in an outer peripheral portion of the effective pixel area 2121.

The control circuit 17 generates a clock signal, a control signal, and the like each of which becomes a reference of operations of the vertical driving circuit 13, the column signal processing circuits 14, the horizontal driving circuit 15, and the like synchronously with a vertical synchronous signal, a horizontal synchronous signal, and a master clock. Also, the clock signal, the control signal, and the like which are generated in the control circuit 17 are inputted to the vertical driving circuit 13, the column signal processing circuits 14, the horizontal driving circuit 15, and the like.

The vertical driving circuit 13, for example, is composed of a shift register, and selects and scans the pixels 11 in the pixel area 12 in order in a vertical direction in increments of rows. Also, the vertical driving circuit 13 supplies pixel signals based on signal electric charges which are generated so as to correspond to quantities of received lights in photodiodes of the pixels 11, respectively, to the column signal processing circuit 14 through respective vertical signal lines 18.

The column signal processing circuit 14, for example, is disposed every column of the pixels 11. Also, the column signal processing circuit 14 executes signal processing such as noise removal and signal amplification for signals outputted from the pixels 11 for one row based on a signal from the OPB area every pixel column. Horizontal selection switches (not shown) are provided between output stages of the column signal processing circuits 14 and a horizontal signal line 19.

The horizontal drive circuit 15, for example, is composed of a shift register. Also, the horizontal drive circuit 15 selects the column signal processing circuits 14 in order by successively outputting horizontal scanning pulse to cause the column signal processing circuits 14 to output the pixel signals to the horizontal signal line 19.

The output circuit 16 executes signal processing for signals which are supplied thereto from the column signal processing circuits 14, respectively, through the horizontal signal line 19, and outputs the resulting signals.

FIG. 2 is a cross sectional view showing a structure of three pixels 11 in the solid-state image pickup element 1 of the first embodiment.

As shown in FIG. 2, light receiving areas 22 each composed of a photodiode are formed in a semiconductor substrate 21 so as to correspond to the pixels 11, respectively.

In FIG. 2, a layer 16 formed on the semiconductor substrate 21 is shown by simplifying layers, such as an insulating layer, which covers the light receiving areas 22.

When the solid-state image pickup element 1 has a surface radiation type structure, a wiring layer is provided between adjacent pixels 11 within the insulating layer, and a gate electrode of a MOS (metal oxide semiconductor) transistor is provided on the semiconductor substrate 21 through a gate insulating film.

On the other hand, when the solid-state image pickup element 1 has a back surface radiation type structure, a gate electrode and a wiring layer of a MOS transistor are provided below with respect to a lower surface of the semiconductor substrate 21.

It is noted that an intra-layer lens, an optical waveguide or the like can also be provided inside the layer 16 as may be necessary.

In addition, a planarizing layer 17 is formed on the layer 16, and color filters 18 of the primary three colors: R, G, and B are formed on a surface which is planarized by the planarizing layer 17.

It is noted that although in the cross section shown in FIG. 2, only the two color filters 18 of Red (R) and the color filter 18 of Green (G) are shown, the color filter 18 of Blue (B) is also formed in a cross section (not shown).

In addition thereto, a planarizing layer 19 is formed so as to cover the color filters 18. Also, microlenses 20 are formed on a surface which is planarized by the planarizing layer 19.

Each of the microlenses 20 is made of a lens formation material, such as SiN or SiO, as a material having a relatively large refractive index than that of any of other layers in such a way that a surface thereof is formed so as to have a curved surface shape.

In the first embodiment of the present disclosure, the solid-state image pickup element 1 shown in FIGS. 1 and 2 will be especially manufactured in the manner as will be described below.

Firstly, by utilizing a well-known manufacturing method in the past, the light receiving areas 22 are formed in the semiconductor substrate 21 shown in FIG. 2, and the layers up to the color filters 18 are formed in order.

It is noted that in the following processes, the color filters 18, and the layers which are formed on and above the color filters 18 are illustrated, and an illustration of the layers which are formed below the color filters 18 is omitted here for the sake of simplicity. This applies to any of embodiments as well in and after a second embodiment.

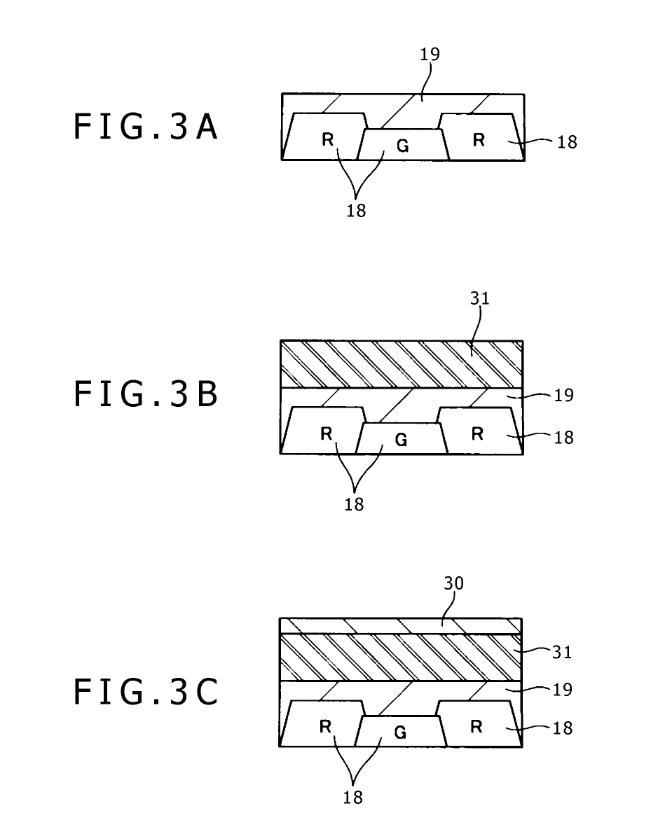

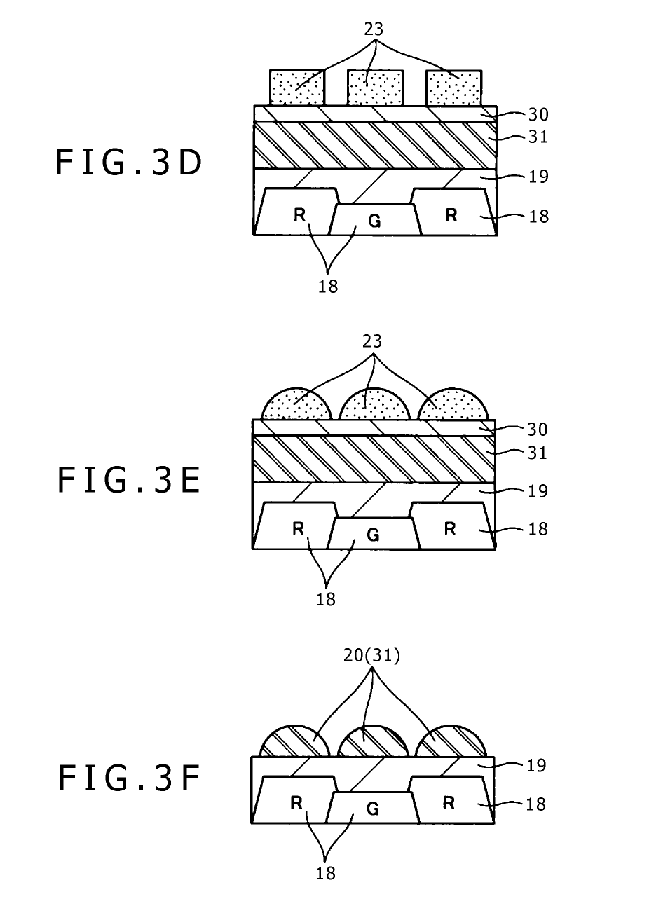

Next, as shown in FIG. 3A, the planarizing layer 19 having a thickness of 0.1 to 1.0 μm is coated over the color filters 18 by utilizing a spin coating method so as to meet the required flatness. An organic material can be used as a material of the planarizing layer 19. In this case, the organic material concerned, for example, includes a siloxane system resin, a styrene system resin, an acrylic resin, an organic material which is obtained by copolymerizing the individual resins, and an organic material which is obtained by containing a metallic oxide filler such as TiO₂ in the resin described above.

Next, as shown in FIG. 3B, a lens base material layer 31 is formed on the planarizing layer 19 so as to have a thickness of 0.5 to 4.0 μm. A material for the microlens 20, that is, an inorganic film such as an oxide film or a nitride film, or an organic film can be used as a material of the lens base material layer 31. In this case as well, the organic film concerned, for example, includes a siloxane system resin, a styrene system resin, an acrylic resin, an organic material which is obtained by copolymerizing the individual resins, and an organic material which is obtained by containing a metallic oxide filler such as TiO₂ in the resin described above. The lens base material layer 31 is formed by utilizing either the spin coating method or a CVD (chemical vapor deposition) method depending on the material thereof.

Next, a material is selected in such a way that a thermal expansion coefficient thereof becomes equal to or larger than that of the resist for a lens shape. Also, as shown in FIG. 3C, an intermediate film 30 is deposited by utilizing a spin coating method so as to have a thickness such that an optical path becomes shorter than a wavelength of a light which is photoelectrically converted in the light receiving area 22. This thickness is equal to or smaller than 0.3 μm, and is preferably equal to or smaller than 0.1 μm. After that, the intermediate film 30 is thermally cured.

For example, when the lens base material layer 31 is composed of an inorganic film made of SiN or SiON, and the resist is composed of either a novolac resin or an acrylic resin, a styrene system resin or the like is used for the intermediate film 30.

Next, after a resist is formed in contact with the intermediate film 30, the resist is exposed by using a mask for lenses. Also, as shown in FIG. 3D, the resist thus exposed is developed, and the resulting resist 23 is patterned into the lenses.

After that, the thermal reflow is carried out, and as shown in FIG. 3E, the resist 23 is formed into the lens shape.

Next, the dry etching is carried out by using an etching gas containing therein an O₂ system gas, and a CF₄ system gas, and as shown in FIG. 3F, the lens shape of the resist 23 is transferred to the lens base material layer 31. As a result, it is possible to form the microlenses 20 each composed of the lens base material layer 31.

During this dry etching process, both of the resist 23 and the intermediate film 30 underlying the resist 23 are removed away.

An etching system and an etching condition at this time, for example, are as follows.

A system such as an Inductively Coupled Plasma (ICP) system, a Capacitively Coupled Plasma (CCP) system, a Transformer Coupled Plasma (TCP) system, a magnetron Reactive Ion Etching (RIE) system, or an Electron Cyclotron Resonance (ECR) system is used as the etching system.

Also, a fluorocarbon gas system gas such as CF₄ or C₄F₈ is used as a primary constituent, and a temperature, a pressure, and the like are suitably adjusted. Under these conditions, the dry etching is carried out.

In addition, the concrete etching conditions, for example, can be set as follows.
Etchback System: Magnetron RIE System
Etching Gas: CF₄ (flow rate: 155 sccm)
High-Frequency Electric Power: 1.8 W/cm²
Etching Room Pressure: 6.65 Pa
Lower Electrode Temperature (Chiller Temperature): 0° C.
Etching Amount: 2.4 μm (in styrene system resist)

The solid-state image pickup element 1 having the structure shown in FIG. 2 can be manufactured in the manner as described above.

According to the method of manufacturing the solid-state image pickup element 1 of the first embodiment, the resist 23 is formed in contact with the intermediate film 30 having the thermal expansion coefficient larger than that of the resist 23 and thereafter, the resist 23 is formed into the lens shape by the thermal reflow. As a result, by the intermediate film 30 having the thermal expansion coefficient larger than that of the resist 23, the force by which the resist 23 is attempting to spread in the phase of the thermal reflow can be suppressed, thereby reducing the slip amount of the resist 23.

Therefore, even when the interval between the adjacent resists 23 is narrowed, the adjacent resists 23 are prevented from being linked to each other. For this reason, it is possible to narrow the interval between the resists 23.

Also, since the lens shape is transferred from the resist 23 to the lens base material layer 31 by carrying out the dry etching, the interval between the microlenses 20 formed from the lens base material layer 31 is narrowed, thereby making it possible to reduce the non-effective area of the microlenses 20. Since the non-effective area of the microlenses 20 can be reduced, the sensitivity of the solid-state image pickup element 1 can be enhanced by reducing the loss due to the non-effective area.

In addition, by adopting the manufacturing method described above, the solid-state image pickup element 1 of the first embodiment can be structured in such a way that the interval between the microlenses 20 is narrowed, and the non-effective area of the microlenses 20 is reduced. As a result, it is possible to structure the solid-state image pickup element 1 in which the loss due to the non-effective area is less, the degree of the light condensing by the microlens 20 is large, and the sensitivity is large.

### 3. Second Embodiment

### Solid-State Image Pickup Element and Method of Manufacturing the Same

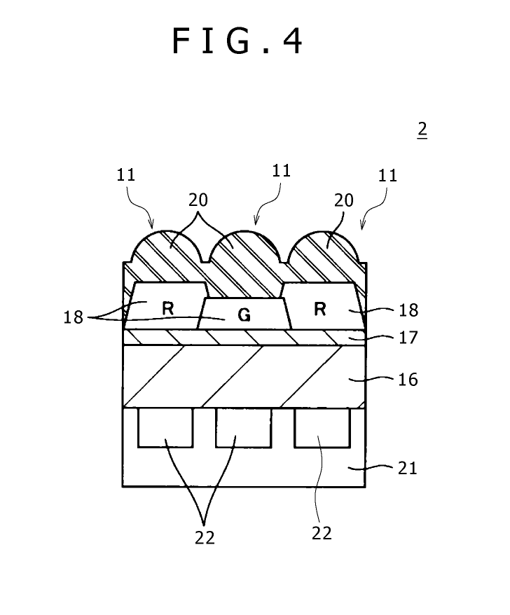

FIG. 4 is a cross sectional view showing a structure of a main portion of a solid-state image pickup element according to a second embodiment of the present disclosure. Also, FIG. 4 shows a cross section of three pixels 11 of a solid-state image pickup element 2 of the second embodiment similarly to the case of the solid-state image pickup element 1 of the first embodiment shown in FIG. 2. It is noted that in the solid-state image pickup element 2 of the second embodiment, constituent elements corresponding to those in the solid-state image pickup element 1 of the first embodiment are designated by the same reference symbols, respectively, and a description thereof is suitably omitted here for the sake of simplicity.

The solid-state image pickup element 2 of the second embodiment has the structure in which the planarizing layer 19 of the solid-state image pickup element 1 of the first embodiment shown in FIG. 2 is omitted.

As shown in FIG. 4, the lens base material layer composing the microlenses 20 is formed over the color filters 18, and the microlenses 20 each of whose surfaces has a curved surface are formed on the lens base material layer.

It is noted that other constituent elements are identical in structure to those of the solid-state image pickup element 1 of the first embodiment, and thus it is possible to adopt the structure shown as the top plan view of FIG. 1.

In the second embodiment of the present disclosure, the solid-state image pickup element 2 shown in FIG. 4 will be especially manufactured in the manner as will be described below.

Firstly, by utilizing a well-known manufacturing method in the past, the light receiving areas 22 are formed in the semiconductor substrate 21 shown in FIG. 4, and the layers up to the color filters 18 are formed in order.

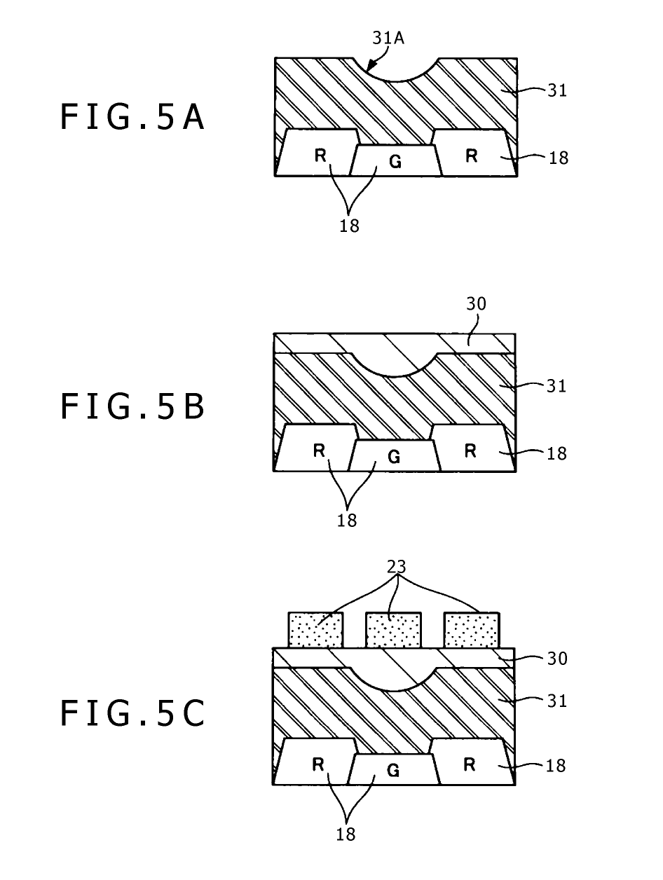

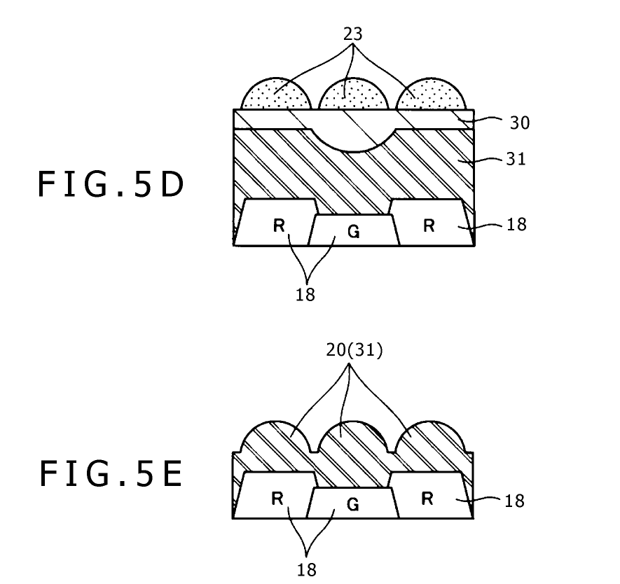

Next, as shown in FIG. 5A, the lens base material 21 is formed over the color filters 18 so as to have the thickness of 0.1 to 4.0 μm. A material for the microlenses 20, that is, an inorganic film such as an oxide film or a nitride film, or an organic film can be used as a material of the lens base material layer 31. In this case as well, the organic film concerned, for example, includes a siloxane system resin, a styrene system resin, an acrylic resin, an organic material which is obtained by copolymerizing the individual resins, and an organic material which is obtained by containing a metallic oxide filler such as TiO₂ in the resin described above. The lens base material layer 31 is formed by utilizing either the spin coating method or a CVD method depending on the material thereof.

At this time, a depression 31A is formed in a portion of the lens base material layer 31 on the color filter 18 of Green (G) which is thinner than each of the color filters 18 of Red (R) so as to correspond to a stepped portion of the color filters 18.

It is noted that in the case of the second embodiment, the thickness of the lens base material layer 31 is set in consideration of both of a depth of the depression 31A of the lens base material layer 31 due to the stepped portion of the color filters 18 and a height of each of the microlenses 20 which will be formed.

Next, as shown in FIG. 5B, the intermediate film 30 is deposited on the lens base material layer 31 by utilizing the spin coating method. At this time, the depression 31A of the lens base material layer 31 shown in FIG. 5A is filled with the intermediate film 30. After that, the intermediate film 30 is thermally cured.

Similarly to the case of the first embodiment, a material is selected for the intermediate film 30 in such a way that a thermal expansion coefficient thereof becomes equal to or larger than that of the resist for a lens shape. The intermediate film 30 is formed so as to have a thickness such that an optical path becomes shorter than a wavelength of a light which is photoelectrically converted in the light receiving area 22. This thickness is equal to or smaller than 0.3 μm, and is preferably equal to or smaller than 0.1 μm.

For example, when the lens base material layer 31 is composed of an inorganic film made of SiN or SiON, and the resist is composed of either a novolac resin or an acrylic resin, a styrene system resin or the like is used for the intermediate film 30.

Next, after the resist has been formed on the intermediate film 30, the resist is exposed by using the mask for lenses. Also, as shown in FIG. 5C, the resist thus exposed is developed, and the resulting resist 23 is patterned into the lenses.

After that, the thermal reflow is carried out, and as shown in FIG. 5D, the resist 23 is formed into the lens shape.

Next, the dry etching is carried out by using an etching gas containing therein an O₂ system gas, and a CF₄ system gas, and as shown in FIG. 5E, the lens shape of the resist 23 is transferred to the lens base material layer 31. As a result, it is possible to form the microlenses 20 each composed of the lens base material layer 31.

During this dry etching process, both of the resist 23 and the intermediate film 30 underlying the resist 23 are removed away.

An etching system and an etching condition at this time, for example, are as follows.

A system such as an ICP system, a CCP system, a TCP system, a magnetron RIE system, or an ECR system is used as the etching system.

Also, a fluorocarbon gas system gas such as CF₄ or C₄F₈ is used as a primary constituent, and a temperature, a pressure, and the like are suitably adjusted. Under these conditions, the dry etching is carried out.

In addition, the concrete etching conditions, for example, can be set as follows.
Etchback System: Magnetron RIE System
Etching Gas: CF₄ (flow rate: 155 sccm)
High-Frequency Electric Power: 1.8 W/cm²
Etching Room Pressure: 6.65 Pa
Lower Electrode Temperature (Chiller Temperature): 0° C.
Etching Amount: 2.4 μm (in styrene system resist)

The solid-state image pickup element 2 having the structure shown in FIG. 4 can be manufactured in the manner as described above.

According to the method of manufacturing the solid-state image pickup element 2 of the second embodiment, the resist 23 is formed in contact with the intermediate film 30 having the thermal expansion coefficient larger than that of the resist 23 and thereafter, the resist 23 is formed into the lens shape by the thermal reflow. As a result, by the intermediate film 30 having the thermal expansion coefficient larger than that of the resist 23, the force by which the resist 23 is attempting to spread in the phase of the thermal reflow can be suppressed, thereby reducing the slip amount of the resist 23.

Therefore, even when the interval between the adjacent resists 23 is narrowed, the adjacent resists 23 are prevented from being linked to each other. For this reason, it is possible to narrow the interval between the resists 23.

Also, since the lens shape is transferred from the resist 23 to the lens base material layer 31 by carrying out the dry etching processing, the interval between the microlenses 20 each formed from the lens base material layer 31 is narrowed, thereby making it possible to reduce the non-effective area of the microlenses 20. Since the non-effective area of the microlenses 20 can be reduced, the sensitivity of the solid-state image pickup element 2 can be enhanced by reducing the loss due to the non-effective area.

In addition, by adopting the manufacturing method described above, the solid-state image pickup element 2 of the second embodiment can be structured in such a way that the interval between the microlenses 20 is narrowed, and the non-effective area of the microlenses 20 is reduced. As a result, it is possible to structure the solid-state image pickup element 2 in which the loss due to the non-effective area is less, the degree of the light condensing by the microlenses 20 is large, and the sensitivity is large.

### 4. Third Embodiment

### Solid-State Image Pickup Element and Method of Manufacturing the Same

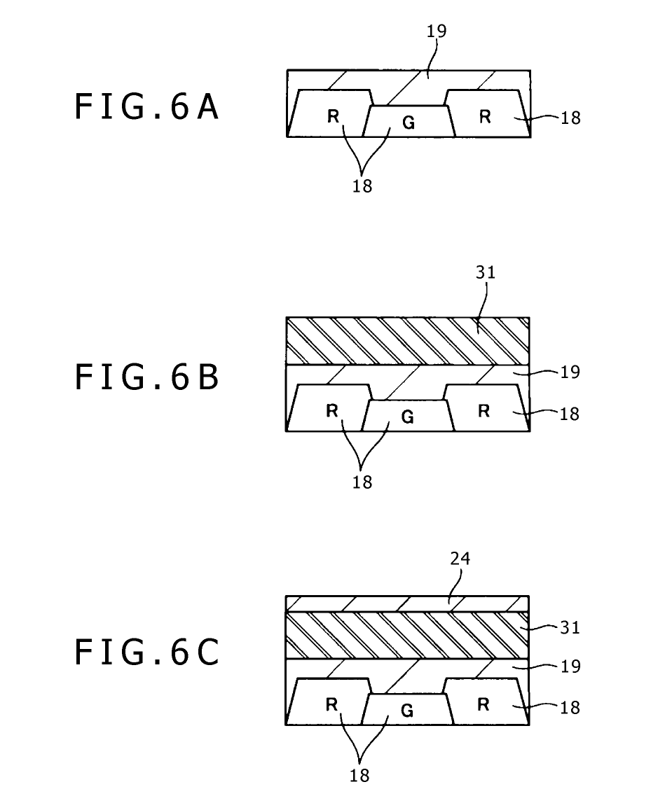

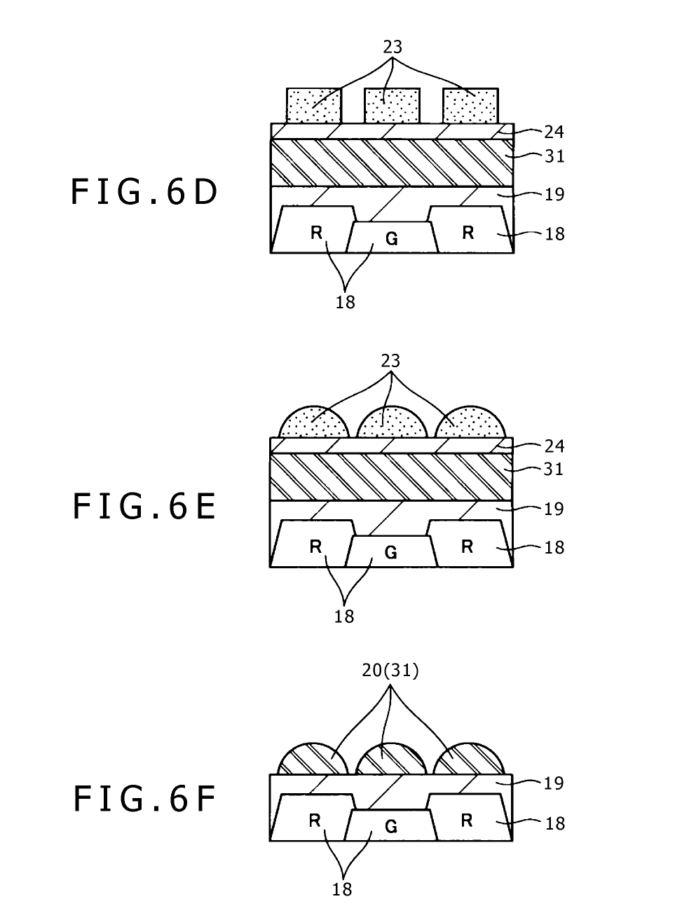

Next, a solid-state image pickup element according to a third embodiment of the present disclosure, and a method of manufacturing the solid-state image pickup element according to the third embodiment of the present disclosure will be described with reference to FIGS. 6A to 6F.

In the third embodiment, the solid-state image pickup element is identical in structure to the solid-state image pickup element 1 of the first embodiment shown in FIGS. 1 and 2. However, the method of manufacturing the solid-state image pickup element is partially different from the method of manufacturing the solid-state image pickup element 1 of the first embodiment.

It is noted that in the solid-state image pickup element of the third embodiment, constituent elements corresponding to those in the solid-state image pickup element 1 of the first embodiment are designated by the same reference symbols, respectively, and a description thereof is suitably omitted here for the sake of simplicity.

In the third embodiment of the present disclosure, the solid-state image pickup element shown in FIGS. 1 and 2 will be manufactured in the manner as will be described below.

Firstly, by utilizing a well-known manufacturing method in the past, the light receiving areas 22 are formed in the semiconductor substrate 21 shown in FIG. 2, and the layers up to the color filters 18 are formed in order.

Next, as shown in FIG. 6A, the planarizing layer 19 having a thickness of 0.1 to 1.0 μm is coated over the color filters 18 by utilizing a spin coating method so as to meet the required flatness. An organic material can be used as a material of the planarizing layer 19. In this case, the organic material concerned, for example, includes a siloxane system resin, a styrene system resin, an acrylic resin, an organic material which is obtained by copolymerizing the individual resins, and an organic material which is obtained by containing a metallic oxide filler such as TiO₂ in the resin described above.

Next, as shown in FIG. 6B, the lens base material layer 31 is formed on the planarizing layer 19 so as to have a thickness of 0.5 to 4.0 μm. A material for the microlenses 20, that is, an inorganic film such as an oxide film or a nitride film, or an organic film can be used as a material of the lens base material layer 31. In this case as well, the organic film concerned, for example, includes a siloxane system resin, a styrene system resin, an acrylic resin, an organic material which is obtained by copolymerizing individual resins, and an organic material which is obtained by containing a metallic oxide filler such as TiO₂ in the resin described above. The lens base material layer 31 is formed by utilizing either the spin coating method or the CVD method depending on the material thereof.

Next, the intermediate film 24 is formed in such a way that a thermal expansion coefficient thereof becomes equal to or larger than that of the resist for a lens shape. Also, as shown in FIG. 6C, the intermediate film 24 is deposited by utilizing a spin coating method so as to have a thickness such that an optical path becomes shorter than a wavelength of a light which is photoelectrically converted in the light receiving area 22. This thickness is equal to or smaller than 0.3 μm, and is preferably equal to or smaller than 0.1 μm. After that, the intermediate film 24 is thermally cured. At this time, a temperature of the thermal curing is lowered to the degree that the intermediate film 24 is not mixed with the resist which will be subsequently formed to intentionally reduce a cure degree, thereby increasing the thermal expansion coefficient of the intermediate film 24. In this respect, the intermediate film 24 in the manufacturing method of the third embodiment is different in structure from the intermediate film 30 in the method of manufacturing the solid-state image pickup element 1 of the first embodiment.

For example, when the temperature in the phase of the thermal reflow of the resist is set to 230° C., a temperature of the thermal curing of the intermediate film 24 is set to 200° C. Since the intermediate film 24 is removed away in the subsequent dry etching process, the intermediate film 24 needs not to be perfectly cured.

Next, after a resist has been formed on the intermediate film 24, the resist is exposed by using a mask for lenses. Also, as shown in FIG. 6D, the resist thus exposed is developed, and the resulting resist 23 is patterned into the lenses.

After that, the thermal reflow is carried out, and as shown in FIG. 6E, the resist 23 is formed into the lens shape.

Next, the dry etching is carried out by using an etching gas containing therein an O₂ system gas, and a CF₄ system gas, and as shown in FIG. 6F, the lens shape of the resist 23 is transferred to the lens base material layer 31. As a result, it is possible to form the microlenses 20 composed of the lens base material layer 31.

During this dry etching process, both of the resist 23 and the intermediate film 24 underlying the resist 23 are removed away.

An etching system and an etching condition at this time, for example, are as follows.

A system such as an ICP system, a CCP system, a TCP system, a magnetron RIE system, or an ECR system is used as the etching system.

Also, a fluorocarbon gas system gas such as CF₄ or C₄F₈ is used as a primary constituent, and a temperature, a pressure, and the like are suitably adjusted. Under these conditions, the dry etching processing is carried out.

In addition, the concrete etching conditions, for example, can be set as follows.
Etchback System: Magnetron RIE System
Etching Gas: CF₄ (flow rate: 155 sccm)
High-Frequency Electric Power: 1.8 W/cm²
Etching Room Pressure: 6.65 Pa
Lower Electrode Temperature (Chiller Temperature): 0° C.
Etching Amount: 2.4 μm (in styrene system resist)

The solid-state image pickup element having the structure shown in FIG. 2 can be manufactured in the manner as described above.

According to the method of manufacturing the solid-state image pickup element of the third embodiment, the resist 23 is formed in contact with the intermediate film 24 having the thermal expansion coefficient larger than that of the resist 23 and thereafter, the resist 23 is formed into the lens shape by the thermal reflow. As a result, by the intermediate film 24 having the thermal expansion coefficient larger than that of the resist 23, the force by which the resist 23 is attempting to spread in the phase of the thermal reflow can be suppressed, thereby reducing the slip amount of the resist 23.

Therefore, even when the interval between the adjacent resists 23 is narrowed, the adjacent resists 23 are prevented from being linked to each other. For this reason, it is possible to narrow the interval between the resists 23.

Also, since the lens shape is transferred from the resist 23 to the lens base material layer 31 by carrying out the dry etching processing, the interval between the microlenses 20 each formed from the lens base material layer 31 is narrowed, thereby making it possible to reduce the non-effective area of the microlenses 20. Since the non-effective area of the microlenses 20 can be reduced, the sensitivity of the solid-state image pickup element can be enhanced by reducing the loss due to the non-effective area.

In addition, by adopting the manufacturing method of the third embodiment described above, the solid-state image pickup element can be structured in such a way that the interval between the microlenses 20 is narrowed, and the non-effective area of the microlenses 20 is reduced. As a result, it is possible to structure the solid-state image pickup element in which the loss due to the non-effective area is less, the degree of the light condensing by the microlenses 20 is large, and the sensitivity is large.

### 5. Modification

A solid-state image pickup element according to a modification of the first embodiment of the present disclosure will be described hereinafter.

If microlenses each having approximately a rectangular shape can be formed by using the technique of the present disclosure, during the etchback, the etching can be made to proceed in a portion in the vicinity of a boundary between the adjacent pixels, thereby reducing a height from the semiconductor substrate to each of the microlenses.

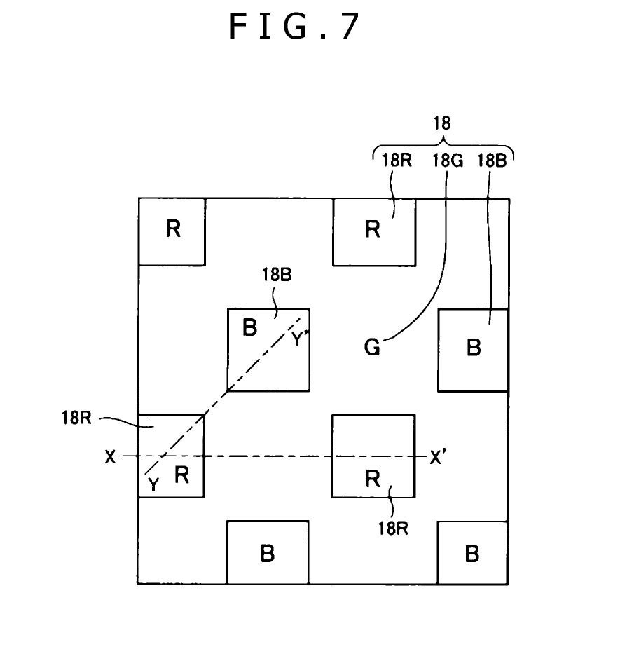

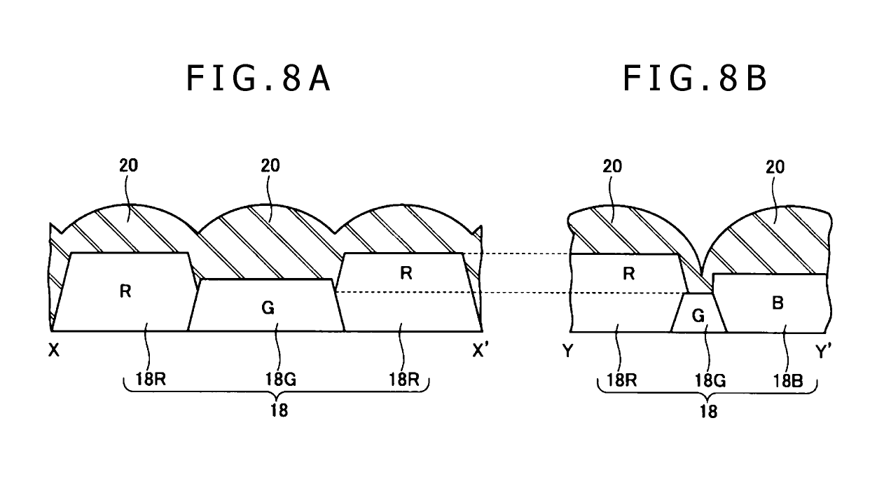

This respect will now be described with reference to a top plan view of FIG. 7, and cross sectional views of FIGS. 8A and 8B.

Let us consider a structure such that as shown in the top plan view of FIG. 7, of the color filters 18, the color filter 18R of Red (R), and the color filter 18B of Blue (B) are formed in an island pattern only in the corresponding pixels, respectively, and the color filter 18G of Green (G) is formed in the corresponding pixel and a portion between the pixels.

When the solid-state image pickup element having this structure is manufactured, in the color filter 18G of Green (G), the portion between the pixels is formed more thinly than the corresponding pixel portion.

FIG. 8A is a cross sectional view taken along line X-X′ of FIG. 7, and FIG. 8B is a cross sectional view taken along line Y-Y′ of FIG. 7. As shown in FIG. 8B, the color filter 18G of Green (G) is formed more thinly in a portion (bridge portion) between the pixels of Green (G) than in a portion of the pixel of Green (G) shown in FIG. 8A.

When the etching is made to proceed by utilizing the bridge portion between the pixels of the color filter 18G of Green (G), a position of a lowermost portion of the microlens 20 is lowered, whereby the microlens 20 can be formed in a lower position. In this case, in the microlenses 20 thus formed, the heights of the microlenses 20 are different from one another between each of the vertical and horizontal directions (longitudinal and transverse directions) of the pixels disposed in a matrix, and the oblique direction. Thus, the height of each of the corresponding microlenses 20 in the oblique direction becomes one to three times as large as that of each of the corresponding microlenses 20 in the horizontal direction.

Also, by applying the manufacturing method of the technique of the present disclosure, it is possible to reduce the width of the non-effective area between the microlenses, and thus it is possible to narrow the interval between the microlenses. Therefore, each of the microlenses can be formed lower than that formed by utilizing the existing manufacturing method.

It is noted that the modification concerned can also apply to any of the second and third embodiments.

### 6. Fourth Embodiment

### Solid-State Image Pickup Element and Method of Manufacturing the Same

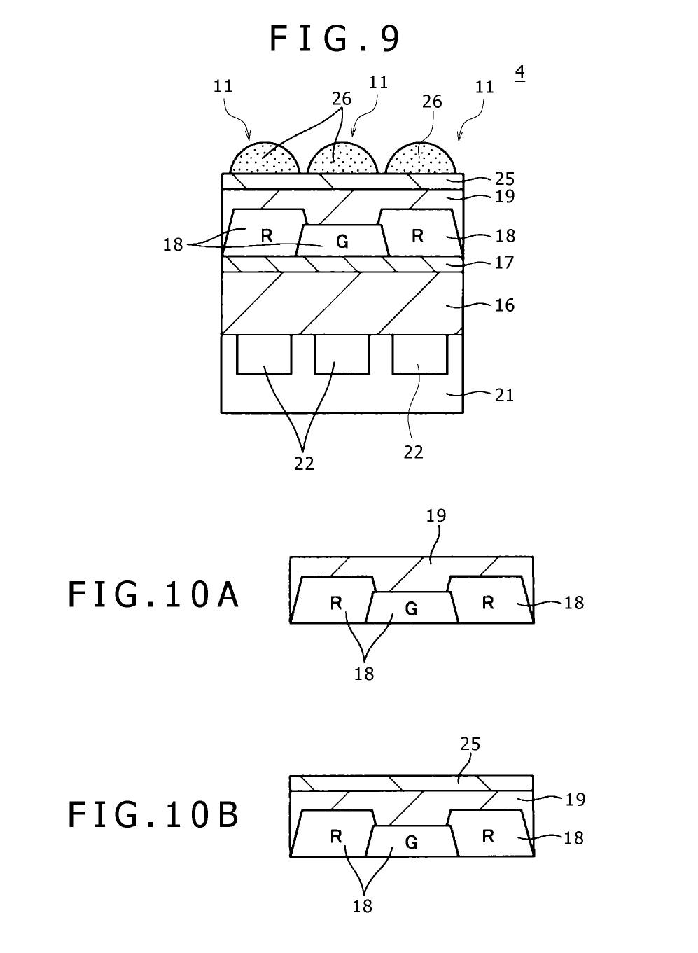

FIG. 9 shows a cross sectional view showing a structure of a main portion of a solid-state image pickup element according to a fourth embodiment of the present disclosure. Also, FIG. 9 shows a cross section of three pixels 11 of a solid-state image pickup element 4 of the fourth embodiment similarly to the case of the solid-state image pickup elements 1 and 2 of the first and second embodiments shown in FIGS. 2 and 4. It is noted that in the solid-state image pickup element 4 of the fourth embodiment, constituent elements corresponding to those in the solid-state image pickup element 1 of the first embodiment are designated by the same reference numerals or symbols, respectively, and a description thereof is suitably omitted here for the sake of simplicity.

The solid-state image pickup element 4 of the fourth embodiment has a structure such that the resist is used directly as each of the lenses.

As shown in FIG. 9, microlenses 26 each of whose surfaces has a curved surface shape are formed on the planarizing layer 19 covering the color filters 18 through an intermediate film 25. The resist is subjected to the thermal reflow to be cured, thereby forming microlenses 26.

Similarly to the case of the intermediate film 30 used in the manufacturing processes in the first or second embodiment of the present disclosure described above, a material having a thermal expansion coefficient which is equal to or larger than that of the resist for resist formation is used in the intermediate film 25.

A thickness of the intermediate film 25 is preferably set to 0.3 μm or less, and is more preferably set to 0.1 μm or less. In particular, when the thickness of the intermediate film 25 is set to 0.1 μm or less, the intermediate film 25 becomes a thin film such that for a light having the shortest wavelength of about 400 nm in the visible light, the reflection from the interface can be ignored, which does not result in the light condensing loss.

It is noted that a structure of other constituent elements in the fourth embodiment is the same as that in the first embodiment and thus it is possible to adopt the structure shown in the top plan view of FIG. 1.

In the fourth embodiment of the present disclosure, the solid-state image pickup element 4 shown in FIG. 9 will be especially manufactured in the manner as will be described below.

Firstly, by utilizing a conventionally known manufacturing method, the light receiving areas 22 are formed in the semiconductor substrate 21 shown in FIG. 9, and the layers up to the color filters 18 are formed in order.

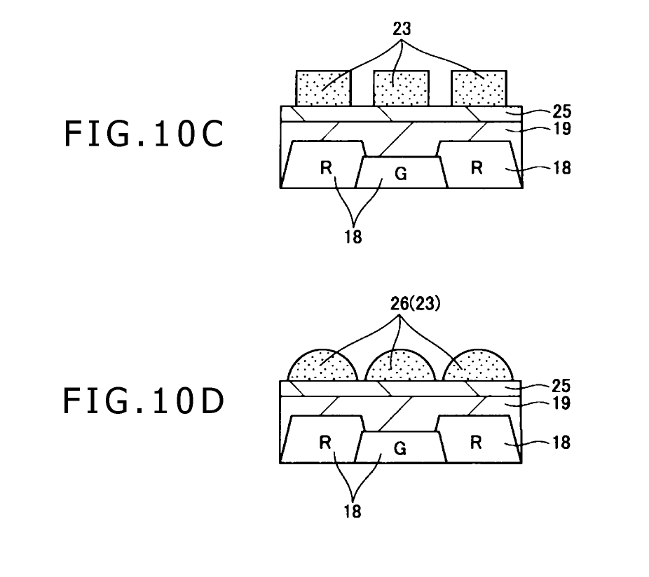

Next, as shown in FIG. 10A, the planarizing layer 19 having a thickness of 0.1 to 1.0 μm is coated over the color filters 18 by utilizing a spin coating method so as to meet the required flatness. An organic material can be used as a material of the planarizing layer 19. In this case, the organic material concerned, for example, includes a siloxane system resin, a styrene system resin, an acrylic resin, an organic material which is obtained by copolymerizing the individual resins, and an organic material which is obtained by containing a metallic oxide filler such as TiO₂ in the resin described above.

Next, a material is selected for the intermediate film 25 in such a way that a thermal expansion coefficient thereof becomes equal to or larger than that of the resist for a lens shape. Also, as shown in FIG. 10B, the intermediate film 25 is deposited by utilizing the spin coating method so as to have a thickness such that an optical path becomes shorter than a wavelength of a light which is photoelectrically converted in the light receiving area 22. This thickness is equal to or smaller than 0.3 μm, and is preferably equal to or smaller than 0.1 μm. After that, the intermediate film 25 is thermally cured.

For example, when the resist is composed of either a novolac resin or an acrylic resin, a styrene system resin or the like is used in the intermediate film 25.

Next, after the resist has been formed on the intermediate film 25, the resist is exposed by using a mask for lenses. Also, the resulting resist thus exposed is developed to pattern the resist 23 into the microlenses as shown in FIG. 10C.

Next, by carrying out the thermal reflow, as shown in FIG. 10D, the resist 23 is formed so as to have the lens shape. As a result, the microlenses 26 each composed of the resist 23 can be formed.

After that, bleaching by an ultraviolet light is carried out as a transparency treatment as may be necessary. For example, the ultraviolet light is radiated to the entire surface.

The solid-state image pickup element 4 having the structure shown in FIG. 9 can be manufactured in the manner as described above.

According to the method of manufacturing the solid-state image pickup element 4 of the fourth embodiment, the resist 23 is formed in contact with the intermediate film 25 having the thermal expansion coefficient larger than that of the resist 23 and thereafter, the resist 23 is formed into the lens shape by the thermal reflow. As a result, by the formation of the intermediate film 25 having the thermal expansion coefficient larger than that of the resist 23, the force by which the resist 23 is attempting to spread in the phase of the thermal reflow process can be suppressed, thereby reducing the slip amount of resist 23.

Therefore, even when the interval between the adjacent resists 23 is narrowed, the adjacent resists 23 prevented from being linked to each other. For this reason, it is possible to narrow the intervals between the resists 23.

Also, since the microlenses 26 each composed of the resist 23 are formed with the resist 23 as the lens shape, the interval between the microlenses 26 is narrowed, thereby making it possible to reduce the non-effective area of the microlenses 26. Since the non-effective area of the microlenses 26 can be reduced, the sensitivity of the solid-state image pickup element 4 can be enhanced by reducing the loss due to the non-effective area.

In addition, by adopting the manufacturing method described above, the solid-state image pickup element 4 of the fourth embodiment shown in FIG. 9 can be structured in such a way that the interval between the microlenses 26 is narrow, and the non-effective area of the microlenses 26 is reduced. As a result, it is possible to structure the solid-state image pickup element in which the loss due to the non-effective area is less, the degree of the light condensing by the microlenses 26 is large, and the sensitivity is large.

In the present disclosure, the configuration of the pixel portion and the peripheral circuit portion of the solid-state image pickup element is by no means limited to the configuration shown in FIG. 1 and thus any other suitable configuration can also be adopted.

In addition, the present disclosure is by no means limited to the CMOS solid-state image pickup element having the configuration shown in FIG. 1 and thus can also be applied to any other suitable type solid-state image pickup element such as a CCD solid-state image pickup element.

In addition thereto, the present disclosure can also be applied to any of a surface radiation type structure in which a wiring layer is formed on the same side as that of lenses in a semiconductor base having a light receiving portion formed therein, and a back surface radiation type structure in which a wiring layer is formed on a side opposite to lenses in a semiconductor base having a light receiving portion formed therein.

In the present disclosure, the semiconductor base composing the light receiving portion is by no means limited to the semiconductor substrate 21, for example, shown in FIGS. 1 and 2. Thus, for example, it is also possible to use a semiconductor base in which a semiconductor epitaxial layer is formed on a semiconductor substrate.

In addition, in the present disclosure, in addition to silicon, a semiconductor such as Ge or a compound semiconductor can also be used as the material of the semiconductor base.

The solid-state image pickup element of the present disclosure, for example, can be applied to a camera system such as a digital camera or a video camera, a mobile phone having an image capturing function, and other apparatuses each having an image capturing function.

### 7. Fifth Embodiment

### Solid-State Image Pickup Element and Method of Manufacturing the Same

### [Cross Sectional View of Pixel]

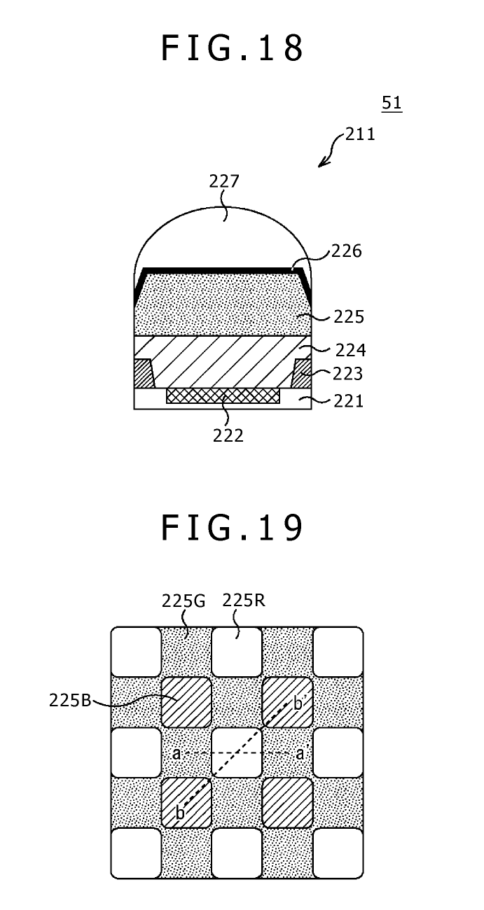

FIG. 18 is a cross sectional view showing a schematic structure of a pixel 211 within an effective pixel area 2121 in a solid-state image pickup element 51 according to a fifth embodiment of the present disclosure.

In the pixel 211, as shown in FIG. 18, a light receiving area 222 composed of a photodiode and the like is formed in a semiconductor substrate 221 such as a silicon substrate. A light blocking film 223 is formed in a boundary portion between each adjacent pixels 211 on the semiconductor substrate 221, and a planarizing film 224 is formed over the light blocking film 223. Also, a color filter 225 of Red (R), Green (G) or Blue (B) is formed on the planarizing film 224. A material which is obtained by adding a pigment of R, G or B as a dye to a photopolymerization negative photosensitive resin is normally used as a material of the color filter 225. An upper surface of the color filter 225 is covered with an inorganic film 226 such as a silicon oxide (SiO₂) film, a silicon nitride (SiN) film, a silicon oxynitride (SiON) film or a silicon carbide (SiC) film. Also, a microlens 227 made of an organic material is formed on the inorganic film 226. The inorganic film 226 functions as an oxygen blocking film (CF cover film) which covers the color filter 225 to block oxygen.

It is noted that in the following description, when R, G, and B of the color filters 225 are distinguished from one another, the color filter 225 of R is referred to as a color filter 225R as well, the color filter of G is referred to as a color filter 225G as well, and the color filter of B is referred to as a color filter 225B as well.

### [Example of Arrangement of Color Filters]

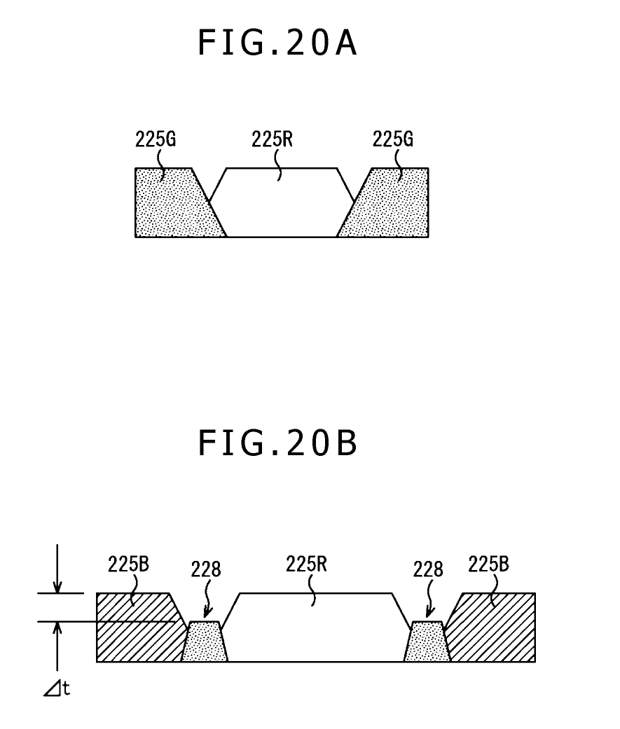

FIG. 19 is a top plan view showing an example of an arrangement of the color filters 225 of R, G, and B. In addition, FIG. 20A is a cross sectional view taken on line a-a′ of FIG. 19, and FIG. 20B is a cross sectional view taken on line b-b′ of FIG. 19.

The color filters 225 adopt a so-called Bayer arrangement in which the color filters of G are disposed in a checkered pattern, and the color filters of R and the color filters of B are disposed in remaining positions in a diagonal direction.

The patterning is carried out in such a way that the color filters of R, G, and B are not uniformly rectangular, but as shown in FIG. 19, the color filters 225G having a large number of pixels are linked to the color filters 225G adjacent to the color filters 225G concerned having a large number of pixels in the diagonal directions in four corners. Also, either the color filter 225R or the color filter 225B is formed in an opening portion of the color filter 225G.

As far as the order in which the color filters 25 of R, G, and B are formed, the color filter 225G having a large number of pixels is firstly formed, and the color filter 225R and the color filter 225B are then formed.

In addition, when the color filters 225 are viewed from the cross section taken on line a-a′ as the horizontal direction, as shown in FIG. 20A, the color filter 225G having a large number of pixels is formed in a taper-like shape so as to overlap the boundary portions with the color filter 225R and the color filter 225B which are subsequently formed. In such a manner, the color filters 225G each having a large number of pixels are formed so as to be linked to one another in the four corners, and are also formed so as to overlap the color filters 225R and the color filters 225B. As a result, the adhesiveness of the color filters 225 is ensured. In addition, it is possible to prevent generation of a gap due to superposition misalignment of the color filters 225. As a result, it is possible to reduce the deterioration of the image quality in the solid-state image pickup element 51.

As can also be seen by viewing the cross sectional view taken on line b-b′ of FIG. 20B, each of linking portions 228 in the four corners in which the color filters 225G are linked to one another is formed a predetermine thickness Δt more thinly than a thickness of each of planar portions of the color filters 225 of R, G, and B. If each of the linking portions 228 is formed so as to have the same thickness as that each of the color filters 225 of R, G, and B, then, a pattern size (pattern width) of each of the linking portions 228 becomes heavy. As a result, an area of the opening portion of the color filters 225G in which either the color filter 225R or the color filter 225B is formed becomes small. Also, when the area of the opening portion of the color filters 225G in which either the color filter 225R or the color filter 225B is formed becomes small, the sensitivity either to the red color or to the blue color is reduced, and the color mixture of the green color component is caused, thereby reducing the sensitivity characteristics of the solid-state image pickup element 51.

In order to cope with such a situation, in the solid-state image pickup element 51, while the color filters 225G are formed so as to be linked to one another in the four corners, each of the linking portions 228 is formed the predetermined thickness Δt thinly than the thickness of each of the color filters 225 of R, G, and B. As a result, the pattern size of the color filters 225G is made as close as to the pixel size, the generation of the gap between the color filters 225, and thus the adhesiveness of the color filters 225 can be ensured.

A method of thinly forming each of the linking portions 228 of the color filter 225G by the predetermined thickness Δt will now be described.

A photo mask in which the pattern size (pattern width) of each of the linking portions 228 of the color filter 225G is set equal to or lower than a resolution limit of a photosensitive resin is used as an exposure mask (photo mask) when the color filter 225G whose linking portions 228 are linked in the four corners is formed. A pattern size of each of the linking portions 228 in the photo mask, for example, is set equal to or smaller than 200 nm. It noted that 200 nm means a size on a wafer to be exposed when a reduction exposure system is used. When the photopolymerization negative photosensitive resin is exposed with an exposure mask size having a pattern size equal to or lower than the limit resolution, the photopolymerization reaction is not sufficiently performed. Thus, a portion having a pattern size equal to or lower than the limit resolution is formed so as to have a small thickness. Therefore, as shown in FIG. 20B, each of the linking portions 228 in the four corners of the color filter 225G having a large number of pixels can be formed the predetermined thickness Δt more thinly than the thickness of each of the planar portions of the color filters 225 of R, G, and B.

It is noted that the arrangement of the color filters 225 is by no means limited to the Bayer arrangement described above and, for example, a stripe-like arrangement, an arrangement including a white filter which transmits lights in the entire visible light region, or the like may also be adopted. In addition, the color of the color filter 225 whose linking portions are linked in the four corners is by no means limited to Green (G). Thus, the color filters each having a large number of pixels within a pixel area 212 (including a solid color) are firstly formed in a linked pattern shape through the patterning.

### [Method of Forming Microlens]

Next, a method of forming the microlens 227 will be described with reference to FIG. 21.

FIG. 21 shows cross sectional views of an effective pixel area 2121 and a non-effective pixel area 2122 within the pixel area 212 in a diagonal direction similarly to the case of line b-b′ of FIG. 19. It is noted that it is supposed that the non-effective pixel area 2122 shown in FIG. 21 is the OPB area.

In a first process, the color filters 225 (225R, 225G, and 225B) of R, G, and B are formed on the planarizing films 224 (refer to FIG. 18) of the effective pixel area 2121 and the non-effective pixel area 2122, respectively, by utilizing the method described with reference to FIG. 19 and FIGS. 20A and 20B.

In a second process, the inorganic films 226 as CF cover films are disposed on the color filters 225 of the effective pixel area 2121 and the non-effective pixel area 2122, respectively. A silicon oxide film, a silicon nitride film, a silicon oxynitride film, a silicon carbide or the like can be used in the inorganic film 226.

In a third process, transparent resin layers 229 each will serve as a material for the microlens 227 are formed on the inorganic films 226 of the effective pixel area 2121 and the non-effective pixel area 2122, respectively. The transparent resin layer 229 is made of an organic material. Thus, for example, a novolac system resin, an acrylic resin, a styrene system resin or plural copolymerization system resists of these resons can be used as the organic material for the transparent resin layer 229.

In a fourth process, resists 241 for formation of the microlenses 227 are patterned into an array-like shape on the transparent resin layer 229 in the effective pixel area 2121 similarly to the case of the arrangement of the pixels 211. That is to say, after the resist 241 has been applied over the transparent resin layer 229 of the entire pixel area 212, a part of the resist 241 in the pixel boundary portion of the effective pixel area 2121, and the non-effective pixel area 2122 is removed away. A photosensitive positive photoresist containing therein a naphthoquinone diazide system photosensitive material in which a novolac system resin is used as base polymer, for example, can be used as the resist 241.

In a fifth process, a heat treatment is carried out for the resist 241 on the transparent resin layer 229 of the effective pixel area 2121, so that the resist 241 obtained through the patterning is deformed (reflowed) to become the lens shape.

In a sixth process, the lens shape of the resist 241 is transferred to the transparent resin layer 229 by utilizing a dry etching method. That is to say, the resist 241 having the lens shape, and the transparent resin layer 229 underlying the resist 241 are selectively etched away at the same time, whereby in the effective pixel area 2121, the lens shape of the resist 241 is transferred to the transparent resin layer 29, while in the non-effective pixel area 2122, the transparent resin layer 229 is gradually thinned (a state of a sixth process (1) shown in FIG. 21). A fluorocarbon system gas such as CF₄, C₂F₆, C₃F₈, C₄F₈, CHF₃ or CH₂F₂, for example, can be used as an etching gas.

When the transparent resin layer 229 in the non-effective pixel area 2122 is gradually etched, so that the inorganic film 226 underlying the transparent resin layer 229 is exposed to the surface (a state of a sixth process (2) shown in FIG. 21), a light corresponding to a reactive product material is generated. The light corresponding to the reactive product material is a light of C—O and Si—C linking when the inorganic film 226 is a silicon oxide film, a light of C—N and Si—C linking when the inorganic film 226 is a silicon nitride film, and a light of Si—F and C—F linking when the inorganic film 226 is a silicon carbide film. Then, in the sixth process, during the process concerned, an intensity of the light corresponding to the reactive product material is detected by using a spectroscope, whereby it is determined whether or not the inorganic film 226 is exposed.

Also, when in the sixth process, it is determined that the intensity of the light corresponding to the reactive product material becomes equal to or larger than a predetermined intensity representing the exposure of the inorganic film 226 in the non-effective pixel area 2122, the process proceeds to a seventh process.

In the seventh process, after the intensity of the light corresponding to the reactive product material has become equal to or larger than the predetermined intensity, a predetermined time previously determined is measured. Also, the etching is ended after a lapse of the predetermined time. As a result, the microlenses 227 are completed, and a gap (an upper portion of the linking portion 228) between the microlenses 227 adjacent to each other in the diagonal direction becomes a state in which the inorganic film 226 is exposed.

At a time point at which the exposure of the inorganic film 226 in the non-effective pixel area 2122 is detected, in the figure, as shown as the sixth process (2), the transparent resin layer 229 still remains on the linking portion 228 of the color filter 225G in the effective pixel area 2121. However, if the thickness of the color filter 225G in the linking portion 228 is equal to that of each of the color filters 225R and 225B adjacent to each other, it may be impossible to continuously carry out the etching after the exposure of the inorganic film 226 in the non-effective pixel area 2122 is detected. The reason for this is because if the etching is continuously carried out, there is the possibility that a part of the color filter 225G in the linking portion 228 is exposed and thus both of the etching system and the semiconductor substrate 221 suffer contamination of the Cu or the like, thereby causing the reduction of the quality of the solid-state image pickup element 51. However, in the solid-state image pickup element 51, the color filter 225G in the linking portion 228 is formed more thinly than any of the color filters 225 adjacent thereto. Then, even after the exposure of the inorganic film 226 in the non-effective pixel area 2122 is detected, the etching can be continuously carried out until the inorganic film 226 in the linking portion 228 is exposed. As a result, each of the microlenses 227 can be formed low in the height thereof (lens position).

According to the manufacturing method described above, the inorganic films 226 for detection of the end point of the etching are formed on the color filters 225 in the effective pixel area 2121 and in the non-effective pixel are 2122, respectively. Also, while the resist 241 having the lens shape, and the transparent resin layer 229 underlying the resist 241 are etched at the same time, the determination about the end point is carried out by using the spectroscope. Also, when the exposure of the inorganic film 226 in the non-effective pixel area 2122 has been detected, the etching is ended with a time point of the exposure thus detected as a reference.

Therefore, the etching amount is not controlled based on the etching time as with the related art, but the etching amount is controlled by detecting the change in the intensity of the light generated due to the exposure of the inorganic film 226 on the color film 225. As a result, it is possible to reduce the disposition of the etching amounts, and it is also possible to reduce the disposition of the sensitivity characteristics of the solid-state image pickup element 51.

When the etching for the transparent resin layer 229 in the effective pixel area 2121 is made to proceed, the inorganic film 226 on the upper surfaces of the linking portions 228 in the four corners of the color filter 225G in the effective pixel area 2121 is exposed. However, the area of each of the upper surfaces of the linking portions 228 in the four corners of the color filter 225G in the effective pixel area 2121 is small as 5% or less of the effective pixel area 2121 as. Thus, it is difficult to detect the end point only based on the exposure of the inorganic film 226 on the upper surfaces of the linking portions 228 because it may be impossible to obtain the sufficient intensity of the light. In order to cope with such a situation, in the present disclosure, the inorganic film 226 is deposited in the non-effective pixel area 2122 as well, whereby the inorganic film 226 in the non-effective pixel area 2122 is early exposed. Since the area in which the inorganic film 226 in the non-effective pixel area 2122 is deposited has an exposure area of 5% or more, it is possible to obtain the sufficient intensity of the light. Therefore, the exposure of the inorganic film 226 on the color filter 225 can be precisely detected by detecting the change in the intensity of the light, which can be made a trigger of the etching end.

It is noted that although as described above, the silicon oxide film, the silicon nitride film, the silicon oxynitride film, the silicon carbide film or the like can be used as the inorganic film 226, of these films, the silicon carbide film is most preferable as the inorganic film 226. The reason for this is because when the inorganic film 226 is composed of either the silicon oxide film or the silicon nitride film, an etching rate between the inorganic film 226 and the organic film (the transparent resin layer 229) becomes the inorganic film: the organic film=1.0:0.5, and when the inorganic film 226 is composed of the silicon carbide film, an etching rate between the inorganic film 226 and the organic film becomes the inorganic film: the organic film=1.0:1.7. Therefore, when the inorganic film 226 is composed of the silicon carbide film, the film reduction after the exposure can be made less as compared with the case where the inorganic film 226 is composed of either the silicon oxide film or the silicon nitride film.

Although in the above case, the non-effective pixel area 2122 is used as the OPB area from which the optical black signal is outputted, the present disclosure is not limited thereto. For example, a dummy bit portion such that no circuit exists within the semiconductor substrate 221, and patterning similar to the case of the effective pixel area 2121 is carried out only on the semiconductor substrate 221 may also be used as the non-effective pixel area 2122 in which the exposure of the inorganic film 226 is detected.

### 8. Sixth Embodiment

### Solid-State Image Pickup Element and Method of Manufacturing the Same

Next, the pixel area 212 in a solid-state image pickup element 61 according to a sixth embodiment of the present disclosure will be described. It is noted that in the solid-state image pickup element 61 of the sixth embodiment, constituent elements corresponding to those in the solid-state image pickup element 51 of the fifth embodiment are designated by the same reference numerals or symbols, respectively, and a description thereof is suitably omitted here for the sake of simplicity.

The sixth embodiment is an embodiment in which the solid-state image pickup element 61 has a cavity structure as shown in FIG. 22. In this case, the effective pixel area 2121 is a depressed central portion of the cavity structure, and the non-effective pixel area 2122 is a peripheral portion which is formed slightly more highly than the depressed central portion. As can be seen, from a first process shown in FIG. 22, a height of the peripheral portion of the cavity structure as the non-effective pixel area 2122 agrees with a height of an upper surface of the color filter 225 (225R, 225G, 225B) of the depressed central portion of the cavity structure as the effective pixel area 2121. In addition, although in the fifth embodiment, the color filters 225 are formed in the non-effective pixel area 2122 as well, in the sixth embodiment, none of the color filters 225 is formed in the non-effective pixel area 2122.

A method of forming the microlenses 227 in the solid-state image pickup element 61 having such a cavity structure will be described below with reference to FIG. 22. It is noted that in a description given with reference to FIG. 22, a duplication portion of the above description given with respect to FIG. 21 is suitably omitted here.

In a first process, the color filters 225 of R, G, and B are formed in the effective pixel area 2121 as the central portion of the cavity structure by utilizing the method given with reference to FIGS. 19, 20A and B.

In a second process, the inorganic film 226 is deposited on both of the color filters 225 of the central portion of the cavity structure, and the peripheral portion of the cavity structure.

In a third process, a transparent resin layer 229 is formed on the inorganic film 226 of both of the central portion of the cavity structure, and the peripheral portion of the cavity structure. The transparent resin layer 229 has the same planar surface (the same height) between the central portion of the cavity structure, and the peripheral portion of the cavity structure.

In processes from a fourth process to a sixth process, the same processes as those in the fifth embodiment described above are carried out. Thus, in the sixth process, the exposure of the inorganic film 26 of the peripheral portion of the cavity structure as the non-effective pixel area 2122 is detected by detecting the light having the predetermined intensity or more by using the spectroscope.

Also, in a seventh process, a predetermined time after the exposure of the inorganic film 226 of the peripheral portion of the cavity structure is detected is measured, and the etching is then ended.

As described above, even in the case where the solid-state image pickup element 61 has the cavity structure, similarly to the case of the fifth embodiment described above, the etching amount is controlled by detecting the change in the intensity of the light generated due to the exposure of the inorganic film 226 of the peripheral portion of the cavity structure. Therefore, it is possible to reduce the disposition of the etching amounts, and it is also possible to reduce the disposition of the sensitivity characteristics of the solid-state image pickup element 61.

Therefore, in any of the fifth and sixth embodiments, it is possible to reduce the disposition of the etching amounts, and it is also possible to reduce the disposition of the sensitivity characteristics of the solid-state image pickup elements 51 and 61.

In addition, with the existing method of controlling an etching amount based on a time parameter, the transparent resin layer 229 made of the microlens material is left in the gap between the adjacent microlenses 227, and also the lens position of each of the microlenses 227 is high. According to the fifth and sixth embodiments of the present disclosure, however, since the etching is carried out until the inorganic film 226 is exposed, the lens position of each of the microlenses 227 can be precisely lowered to a lower limit, and thus the characteristics of the sensitivity to the oblique incident light are improved. In addition, since the linking portion 28 is formed thinly by the predetermined thickness of Δt, it is possible to lower the lens position of each of the microlenses 227, and thus the characteristics of the sensitivity to the oblique incident light are further improved. In addition thereto, the inorganic film 226 for detection of the end point functions as the oxygen blocking film as well.

Although the height of the peripheral portion of the cavity structure is made equal to the height of the upper surface of each of the color filters 225 of the central portion of the cavity structure as the effective pixel area 2121 in the sixth embodiment, it is only necessary that the height of the peripheral portion of the cavity structure is equal to or higher than the upper surface of each of the color filters 25. That is to say, all it takes is that there is set the height such that the inorganic film 226 of the non-effective pixel area 2122 is exposed earlier than the inorganic film 226 of the effective pixel area 2121.

### 9. Seventh Embodiment

### Solid-State Image Pickup Element and Method of Manufacturing the Same

Next, the pixel area 212 in a solid-state image pickup element 71 according to a seventh embodiment of the present disclosure will be described hereinafter. It is noted that in the solid-state image pickup element 71 of the seventh embodiment, constituent elements corresponding to those of the solid-state image pickup element 51 of the fifth embodiment are designated by the same reference numerals or symbols, respectively, and a description thereof is suitably omitted here for the sake of simplicity.

In the fifth embodiment described above, the film (the inorganic film 226), for detection of the end point, which is deposited on the color filters 225 is made of the inorganic material, while the organic material is used as the material of each of the microlenses 227. On the other hand, in each of the seventh embodiment and an eighth embodiment which will be described below, a film, for detection of the end point, which is deposited on the color filters 225 is made of an organic material, while an inorganic material is used as a material of each of the microlenses 227.

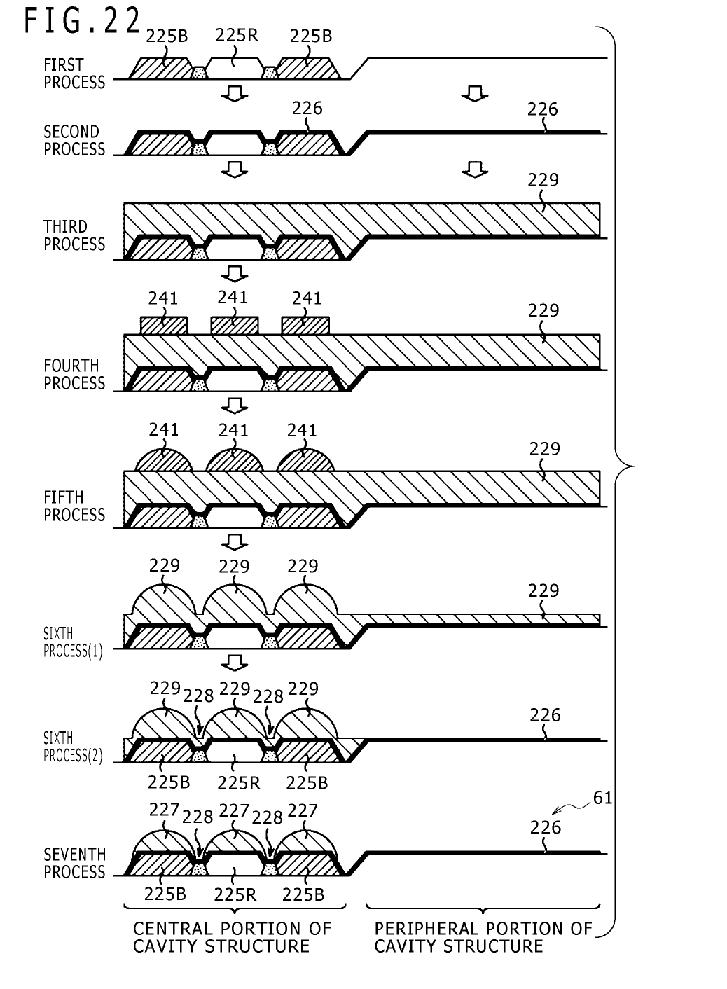

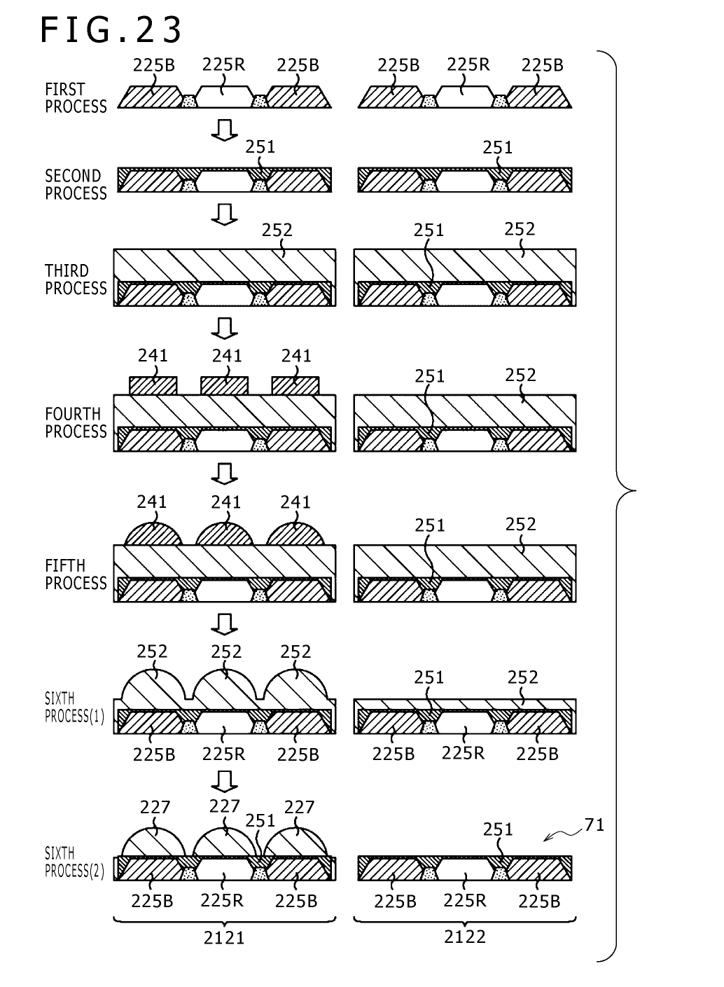

A method of forming the microlenses 227 in the solid-state image pickup element 71 of the seventh embodiment will be described below with reference to FIG. 23. The seventh embodiment adopts a form such that an organic material is substituted for the material of the CF cover film in the fifth embodiment, and an inorganic material is substituted for the material of each of the microlenses 227. It is noted that in a description which will be given with reference to FIG. 23 as well, a duplication portion of the above description given with respect to FIG. 21 is suitably omitted here.

In a second process, an organic film 251 is applied to the color filters 225 in the effective pixel area 2121 and the non-effective pixel area 2122 by utilizing the spin coating method. The organic film 251, for example, is composed of a novolac system resin, an acrylic resin, a styrene system resin or plural copolymerization system resin of these resins.

In a third process, inorganic material layers 252 each serving as a material for each of the microlenses 227 are formed on the organic films 251 in the effective pixel area 2121 and the non-effective pixel area 2122, respectively. A silicon oxide film, a silicon nitride film, a silicon oxynitride film, a silicon carbide film or the like can be used as the material of the inorganic material layer 252.

In processes from a fourth process to a sixth process, the same processes as those in the fifth embodiment described above are carried out. In the sixth process, when the etching for the inorganic material layer 252 proceeds, the organic film 251 in the non-effective pixel area 2122 is exposed. Also, the change in the intensity of the light corresponding to the reactive product material due to the exposure of the organic film 251 in the non-effective pixel area 2122 is detected by using the spectroscope, and the etching is then ended. As a result, in the effective pixel area 2121, the lens shape of the resist 241 is transferred, thereby completing the microlenses 227. The etching is continuously carried out until the organic film 251 is exposed, whereby each of the microlenses 227 can be formed low in height.

In the seventh embodiment as well, the etching amount is controlled by detecting the change in the intensity of the light due to the exposure of the organic film 251 in the non-effective pixel area 2122. Therefore, it is possible to reduce the disposition of the etching amounts, and it is also possible to reduce the disposition of the sensitivity characteristics of the solid-state image pickup element 71.

### 10. Eighth Embodiment

### Solid-State Image Pickup Element and Method of Manufacturing the Same

Next, the pixel area 212 in a solid-state image pickup element 81 according to an eighth embodiment of the present disclosure will be described hereinafter. The eighth embodiment is an embodiment which has a cavity structure as with the sixth embodiment described above, and in which a CF cover film is composed of an organic film, and a material of each of microlenses 227 is an inorganic material. It is noted that in the solid-state image pickup element 81 of the eight embodiment, constituent elements corresponding to those of the solid-state image pickup element 51 of the fifth embodiment are designated by the same reference numerals or symbols, respectively, and a description thereof is suitably omitted here for the sake of simplicity.

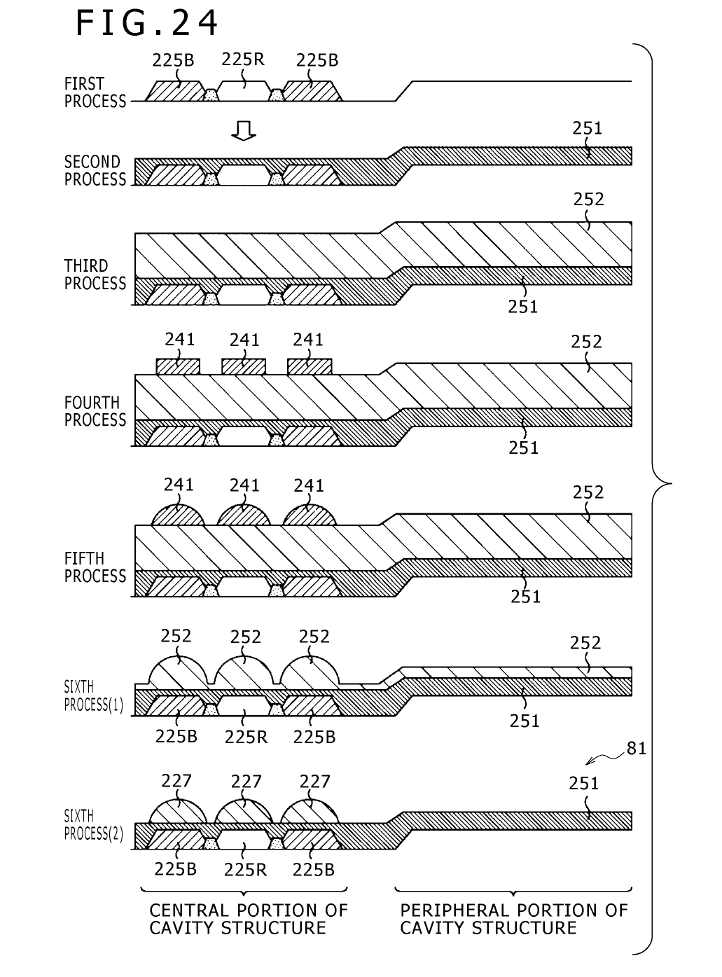

A method of forming the microlenses 227 in the solid-state image pickup element 81 of the eighth embodiment will be described below with reference to FIG. 24. It is noted that in a description which will be given with reference to FIG. 24 as well, a duplication portion of the above description given with respect to FIG. 21 is suitably omitted here.

In processing in a second step, the organic film 251 is applied to both of the color filters 225 in the central portion of the cavity structure, and the peripheral portion of the cavity structure. The organic film 251, for example, is composed of a novolac system resin, an acrylic resin, a styrene system resin or plural copolymerization system resin of these resins.

In a third process, the inorganic material layers 252 are formed on the inorganic films 226 of both of the central portion of the cavity structure, and the peripheral portion of the cavity structure, respectively. A silicon oxide film, a silicon nitride film, a silicon oxynitride film, a silicon carbide film or the like can be used as the material of the inorganic material layer 252 similarly to the case of the fifth embodiment.

In processes from a fourth process to a sixth process, the same processes as those in the fifth embodiment described above are carried out. Also, in the sixth process, when the etching for the inorganic material layer 252 proceeds, and thus the organic film 251 in the peripheral portion of the cavity structure is exposed, the light having the predetermined intensity or more is detected by using the spectroscope, and the etching is then ended. As a result, in the central portion of the cavity structure, the etching is continuously carried out until the organic film 251 is exposed from the gap of the inorganic material layer 252 having the lens shape, thereby forming the microlenses 227.

In the eighth embodiment as well, the etching amount is controlled by detecting the change in the intensity of the light generated due to the exposure of the organic film 251 in the peripheral portion of the cavity structure as the non-effective pixel area 2122. Therefore, it is possible to reduce the disposition of the etching amounts, and it is also possible to reduce the disposition of the sensitivity characteristics of the solid-state image pickup element 81.

Therefore, in any of the seventh and eighth embodiments, it is possible to reduce the disposition of the etching amounts, and it is also possible to reduce the disposition of the sensitivity characteristics of the solid-state image pickup elements 71 and 81.

In addition, with the existing method of controlling an etching amount based on a time parameter, the inorganic material layer 252 made of the microlens material is left in the gap defined between the adjacent microlenses 227, and also the lens position of each of the microlenses 227 is high. According to the seventh and eighth embodiments of the present disclosure, however, since the etching is carried out until the organic film 251 is exposed, the lens position of each of the microlenses 227 can be precisely lowered to a lower limit, and thus the characteristics of the sensitivity to the oblique incident light are improved. The microlenses 227 each composed of the inorganic material layer 252 each function as the oxygen blocking film as well.

When the inorganic material layer 252 is composed of either the silicon oxide film or the silicon nitride film, an etching rate between the inorganic material layer 252 and the organic film 251 becomes 1.0:0.5, and when the inorganic material layer 252 is composed of the silicon carbide film, an etching rate between the inorganic material layer 252 and the organic film 251 becomes 1.0:1.7. Therefore, in the seventh and eighth embodiments, for the purpose of decreasing the film reduction of the organic film 251 after completion of the exposure, contrary to each of the fifth and sixth embodiments, as far as the material of the inorganic material layer 252 concerned, either the silicon oxide film or the silicon nitride film is preferable rather than the silicon carbide film.

The fifth to eighth embodiments described above are summarized as follows. When one of the organic film (organic material layer) or the inorganic film (inorganic material layer) is used as a first film and the other thereof is used as a second film, the first film is formed as the film, for detection of the end point, which is formed on the color filters 225, and the second film is formed on the first film. Also, in the etching processes for transferring the lens shape of the resist 241 to the second film, the etching is ended by detecting the change in the intensity of the light generated due to the exposure of the first film of the non-effective pixel area 2122. As a result, it is possible to reduce the disposition of the etching amounts, and it is also possible to reduce the disposition of the sensitivity characteristics of the solid-state image pickup elements 51, 61, 71, and 81.

All it takes is that the height of the base surface of the first film in the non-effective pixel area 2122 as the area in which the change in the intensity of the light generated due to the exposure of the first film is detected is equal to or higher than that of each of the upper surfaces of the color filters 225 in the effective pixel area 2121.

### 11. Ninth Embodiment

### Structure of Color Filters in Solid-State Image Pickup Device

### [Top Plan View and Cross Sectional View of Color Filters]

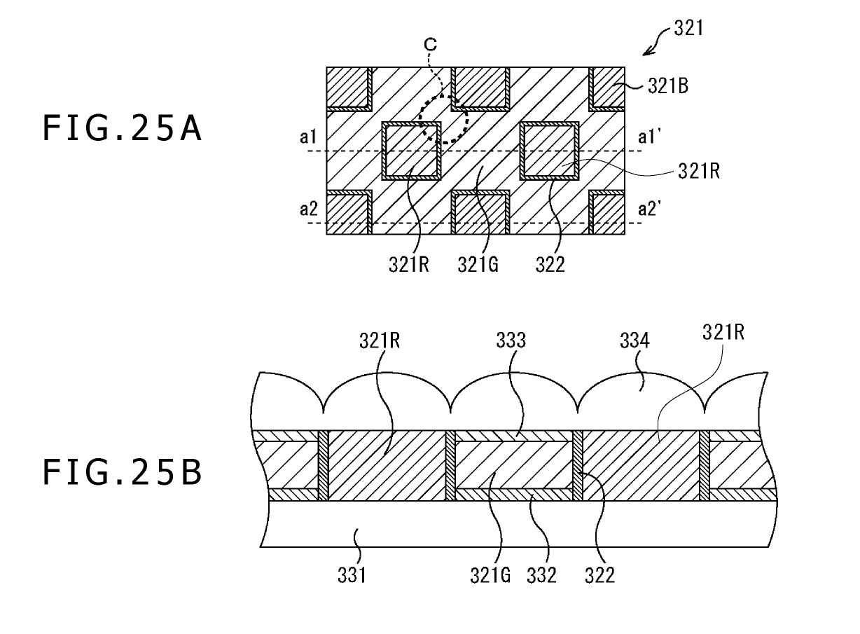

FIGS. 25A and 25B are respectively a top plan view and a cross sectional view showing color filters provided in a solid-state image pickup device according to a ninth embodiment to which the present disclosure is applied. Here, FIG. 25A is a top plan view showing a structure of the color filters, and FIG. 25B is a cross sectional view of the color filters taken on line a1-a1′ of FIG. 25A. It is noted that since a cross sectional view of the color filters taken on line a2-a2′ of FIG. 25A is basically the same as that shown in FIG. 25B, an illustration thereof is omitted here for the sake of simplicity. In addition, the solid-state image pickup device may be composed of a Charge Coupled Device (CCD) image sensor or a Complementary Metal Oxide Semiconductor (CMOS) image sensor.

Color filters 321 shown in FIGS. 25A and 25B exhibit a so-called Bayer arrangement in which each of the color filters 321 is composed of filters 321R, 321G, and 321B corresponding to color components of the three primary colors: R, G, and B corresponding to plural pixels, respectively, and the filters 321R, 321G, and 321B corresponding to color components of the three primary colors: R, G, and B are each disposed in a lattice.

As shown in FIG. 25A, each of the filters 321R, 321G, and 321B is formed approximately in a square. However, as shown in the figure by a portion C indicated by a broken line, the filters 321G are formed so as to be linked to one another in at least parts thereof. Specifically, each of the filters 321G is formed in such a way that four corners thereof are linked to four corners of the filters 321G adjacent to the filter 321G concerned, respectively. In addition, a light attenuating film 322 for attenuating a light which is transmitted through the light attenuating film 322 having a transmittance is formed in a boundary between the filter 321G and the filter 321R, and a boundary between the filter 321G and the filter 321B.

As shown in FIG. 25B, the color filters 321 (the filters 321R and 321G) are formed on an inorganic film 331. However, the filter 321G is formed on an organic film 332 formed on the inorganic film 331. As a result, a bottom surface of the filter 321R (the filter 321B) is formed lower than that of the filter 321G. In addition, an inorganic film 333 is formed on an upper surface of the filter 321G, so that an upper surface of the filter 321R (the filter 321B), and an upper surface of the inorganic film 333 are formed so as to be flush with each other. Also, microlenses 334 are provided on the upper surfaces of the color filters 321 so as to correspond to the filters 321R, 321G, and 321B (that is, the pixels), respectively. That is to say, the light attenuating film 322 has a function of attenuating the light which is being transmitted through the light attenuating film 322 having the transmittance of incident lights from the microlenses 334.

### [Top Plan View and Cross Sectional View of Solid-State Image Pickup Device]

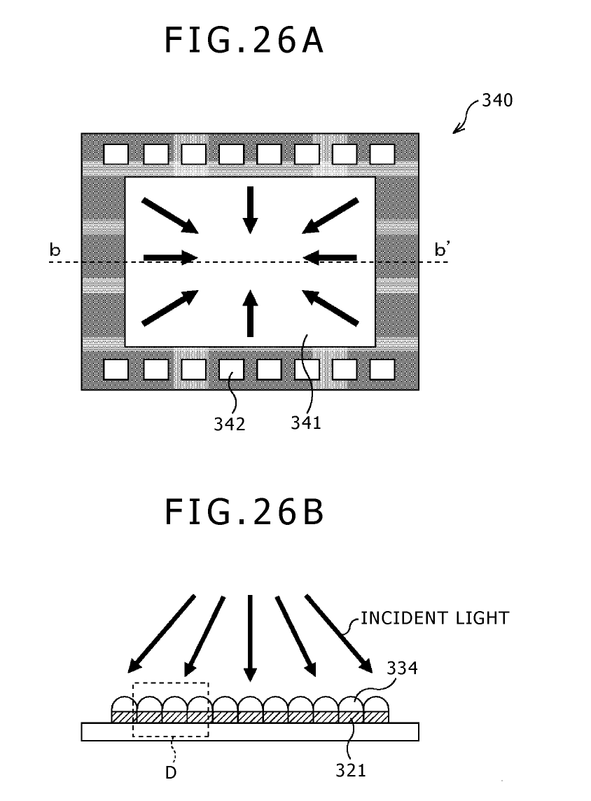

FIGS. 26A and 26B are respectively a top plan view and a cross sectional view showing a structure of the solid-state image pickup device of the ninth embodiment including the color filters described above.

FIG. 26A is a top plan view showing an external appearance structure of the solid-state image pickup device, and FIG. 26B is a cross sectional view of the solid-state image pickup device taken on line b-b′ of FIG. 26A. As shown in FIG. 26A, a light receiving area 341 as an area in which a pixel array having plural pixels disposed therein in a matrix is arranged is provided in a center of a solid-state image pickup device 340. As shown in FIG. 26B, the color filter 321 and the microlens 334 are provided every pixel on an upper surface of the light receiving area 341. Thus, incident lights from an optical lens (not shown) are made incident to the microlenses 334 and the color filters 321. It is noted that the color filters 321 are provided above a substrate (not shown) including a wiring layer, a pixel array, and the like. In addition, in FIG. 26A, bonding pads 342 as terminals to which gold wires are connected, respectively, are disposed on an upper side and a lower side of the light receiving area 341 in the figure. Thus, the gold wires connected to the bounding pads 342, respectively, are connected to the substrate (no shown) by utilizing a wire bonding method.

Here, as shown in FIG. 26B, the incident lights from the optical lens (not shown) are made incident vertically to the solid-state image pickup device 340 in the center of the light receiving area 341. However, an incidence angle becomes large as the light incidence portion becomes closer to the periphery of the light receiving area 341.

That is to say, the lights made incident to the microlenses 334 corresponding to the pixels, respectively, need to be made incident to photodiodes (PD) composing the pixels through the corresponding color filters 321, respectively. Thus, in general, the color filters 321 and the microlenses 334 corresponding to the PDs, respectively, are designed in such a way that positions thereof are shifted to directions indicated by heavy arrow marks shown in the light receiving area 341 of FIG. 26A, that is, in the central direction of the light receiving area 341 with respect to the corresponding pixels. In this case, a shift amount becomes large as the light incidence portion becomes closer to the periphery of the light receiving area 341.

### [With Respect to Incident Lights Made Incident to Light Receiving Area of Solid-State Image Pickup Device]

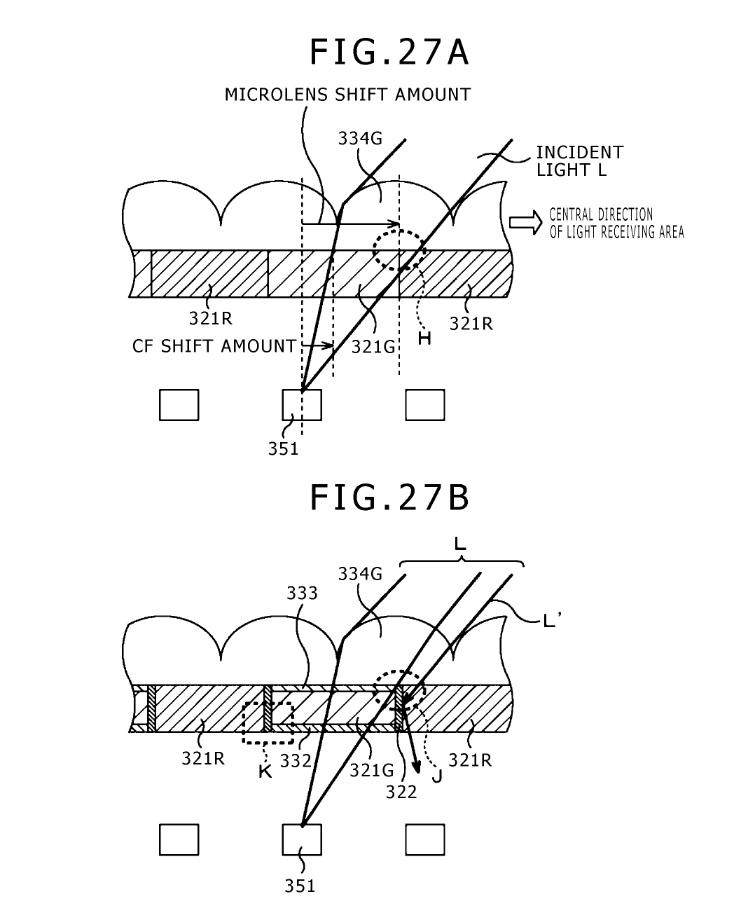

Here, the incident lights made incident to a portion D, indicated by broken line, of the solid-state image pickup device 340 shown in FIG. 26B will be described below with reference to FIGS. 27A and 27B.

FIG. 27A shows a portion corresponding to the portion D, indicated by the broken line of FIG. 26B in an existing solid-state image pickup device. Referring to FIG. 27A, as described above, the existing solid-state image pickup device is designed in such a way that a light which has been incident to a microlens 334G corresponding to a G pixel is made incident to a PD 351 composing the G pixel through a corresponding filter 321G. Specifically, the microlens 334G and the filter 321G each corresponding to the PD 351 are shifted in a central direction (in a right-hand direction in the figure) of the light receiving area 341 so as to correspond to an incidence angle of the incident light L. It is noted that the design is carried out in such a way that a shift amount (microlens shift amount) of microlens 334G with respect to the PD 351, and a shift amount (CF shift amount) of filter 321G with respect to the PD 351 are identical to each other, or the microlens shift amount becomes larger than the CF shift amount.

Now, referring to FIG. 27A, as shown in the figure by a portion H indicated by a broken line, with regard to the incident light L made incident to the microlens 334G which is formed so as to correspond to the filter 321G, a part thereof passes through a part of the filter 321R adjacent to the filter 321G to be made incident to the PD 351 correspond to the G pixel. That is to say, a green color light made incident from the filter 321G to the PD 351 correspond to the G pixel is mixed with a red color light from the filter 321R to generate the color mixture, thereby deteriorating the color reproducibility of the solid-state image pickup device 340.

On the other hand, FIG. 27B shows a portion corresponding to the portion D indicated by the broken line of FIG. 26B in the solid-state image pickup device 340 of the ninth embodiment to which the present disclosure is applied.

Referring now to FIG. 27B, of the incident lights L made incident to the microlens 334G which is formed so as to correspond to the filter 321G, as shown in the figure by a portion J indicated by a broken line, an incident light L′ passing through a part of the filter 321R adjacent to the filter 321G is either reflected or absorbed by the light attenuating film 322 formed in the boundary between the filter 321G and the filter 321R.

As a result, it is possible to suppress the generation of the color mixture described above, and it is also possible to suppress the deterioration of the color reproducibility of the solid-state image pickup device.

It is noted that as described above, the incidence angles of the incident lights made incident to the microlenses and the color filters not only differ depending on the pixel positions in the light receiving area, but also are changed depending on an F value as well in an electronic apparatus such as a digital camera. Therefore, it is feared that it may be impossible to sufficiently suppress the generation of the color mixture only by forming the light attenuating film in the boundary between the adjacent filters.

[With respect to Bottom Surface of Light Attenuating Film]

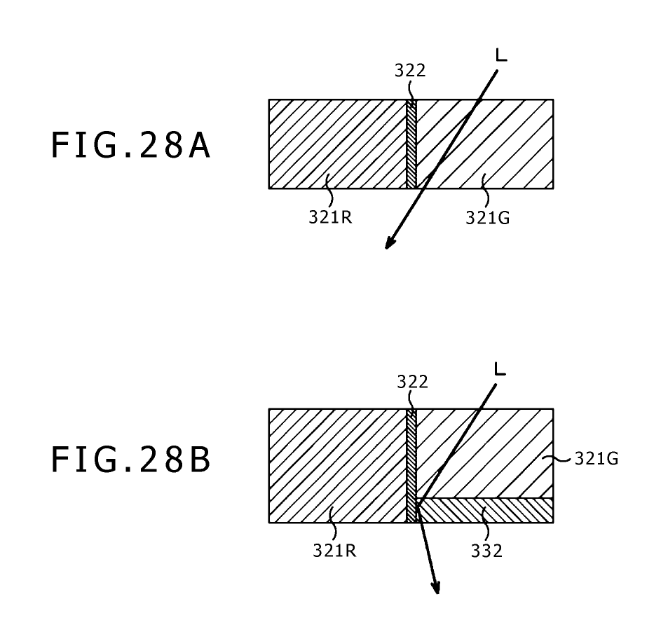

Here, an incident light made incident to a portion K indicated by a broken line and shown in FIG. 27B will be described below with reference to FIGS. 28A and 28B.

FIG. 28A shows a portion corresponding to the portion K indicated by the broken line of FIG. 27B in the solid-state image pickup device 340 in which the light attenuating film 322 is provided in the boundary between the adjacent filters 321G and 321R.

Referring now to FIG. 28A, although the light attenuating film 322 is provided between the filter 321G and the filter 321R, bottom surfaces of the light attenuating film 322, and the filter 321G and the filter 321R are made flush with one another. In this case, as shown in FIG. 28A, the incident light L which has been made incident to the filter 321G to pass through a lower end of the light attenuating film 322 is made incident to the PD of the R pixel corresponding to the filter 321R adjacent to the filter 321G to generate the color mixture.

On the other hand, FIG. 28B shows a portion corresponding to the portion K indicated by the broken line of FIG. 27B in the solid-state image pickup device 340 of the ninth embodiment to which the present disclosure is applied.

Referring to FIG. 28B, the light attenuating film 322 is formed between the filter 321G and the filter 321R. Also, each of bottom surfaces of the filter 321R and the light attenuating film 322 is formed lower than that of the filter 321G. As a result, in the structure shown in FIG. 28A, the light L which has been made incident to the PD of the R pixel corresponding to the filter 321R adjacent to the filter 321G is either reflected or absorbed by the light attenuating film 322.

As a result, it is possible to further suppress the generation of the color mixture, and it is also possible to more reliably suppress the deterioration of the color reproducibility in the solid-state image pickup device. In particular, it is possible to suppress the color mixture in which either the red color light or the blue color light is mixed with the green color light. Therefore, it becomes possible to sufficiently suppress the influence of the color mixture in the solid-state image pickup device including the color filters exhibiting the Bayer arrangement in which the G pixels the number of which is twice that of each of the R pixels and the B pixels are provided.

### [Processing for Forming Color Filters]

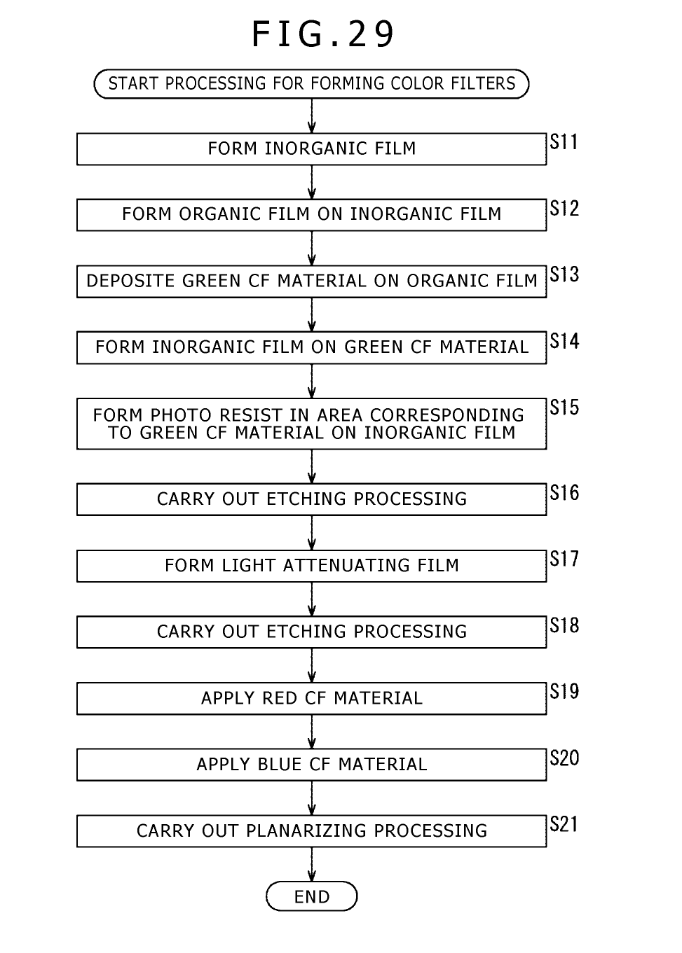

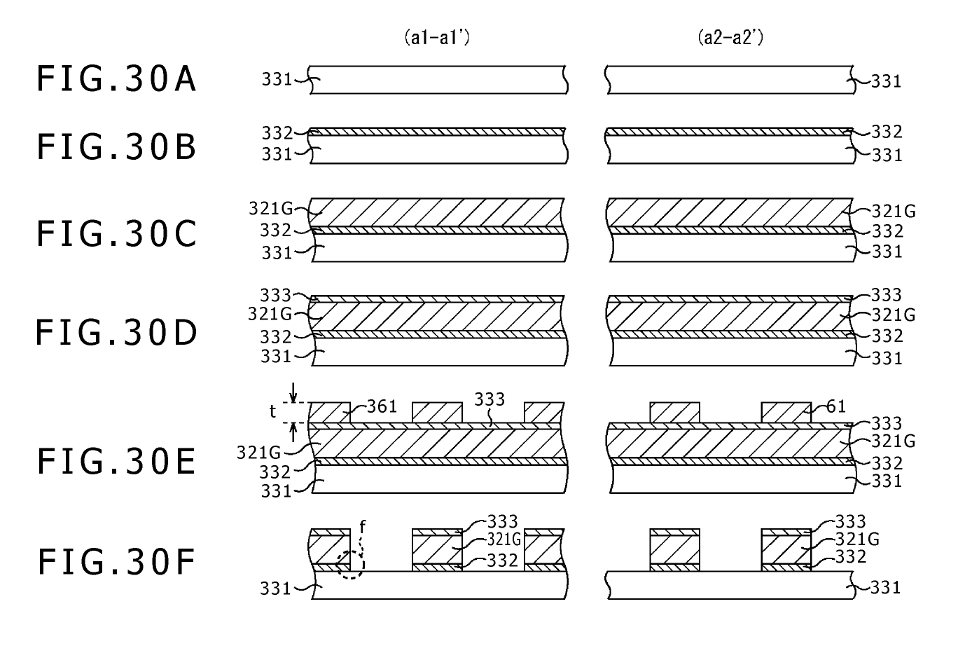

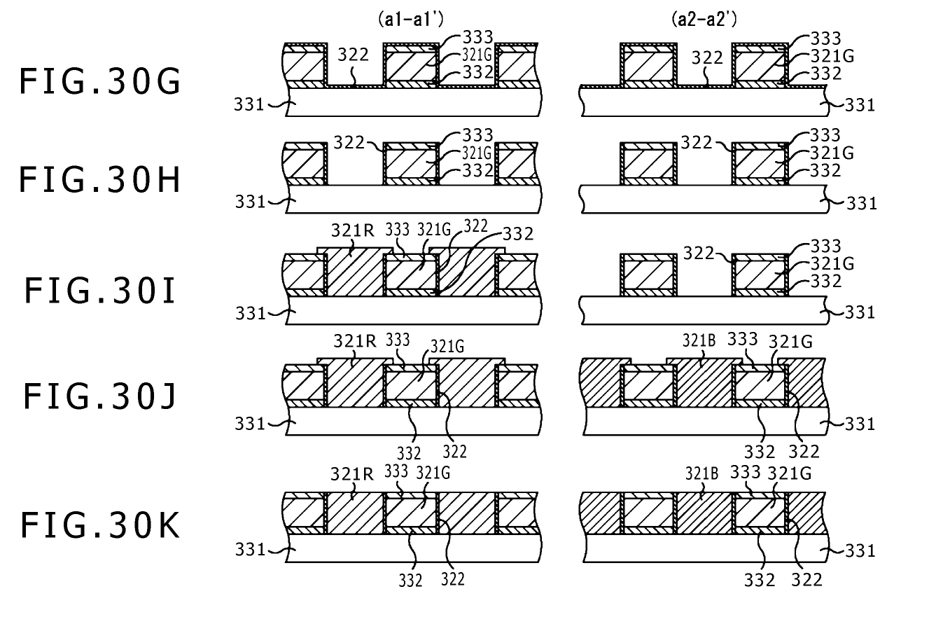

Next, processing for forming the color filters 321 in processes for manufacturing the solid-state image pickup device 340 including the color filters 321 shown in FIGS. 25A and 25B will be described below with reference to FIG. 29 and FIGS. 30A to 30K. FIG. 29 is a flow chart explaining processing for forming the color filters 321 shown in FIGS. 25A and 25B. Also, FIGS. 30A to 30K are respectively cross sectional views of the color filters 321 in the forming processes. In particular, in each of FIGS. 30A to 30K, a left-hand side part thereof shows a cross sectional view of the color filters 321 taken on line a1-a1′ of FIG. 25A, and a right-hand side part thereof shows a cross sectional view of the color filters 321 taken on line b1-b1′ of FIG. 25A.

Firstly, in processing in Step S11, as shown in FIG. 30A, the inorganic film 331 is formed. Specifically, for example, a plasma silicon oxide (P—SiO) film, a plasma silicon nitride (P—SiN) film or a plasma silicon oxynitride (P—SiON) film is formed as the inorganic film 331.

In processing in Step S12, as shown in FIG. 30B, the organic film 332 is formed on the inorganic film 331. Specifically, for example, an acrylic system, styrene system or epoxy system resin is formed as the organic film 332 in a heat treatment at about 150 to 250° C. on the inorganic film 331 by utilizing a spin coating method. It is noted that a thickness of the organic film 332 is preferably equal to or smaller than 200 nm.

In processing in Step S13, as shown in FIG. 30C, the green color filter (CF) material 321G is deposited on the organic film 332. A dye addition type thermosetting resin, for example, is used as the CF material 321G. The deposition is carried out in such a way that after the dye addition type thermosetting resin has been applied onto a wafer (not shown) by utilizing the spin coating method, the dye addition type thermosetting resin thus applied is thermally cured at about 180 to 220° C. It is noted that in this case, a dye addition type photo resist may be used instead of using the dye addition type thermosetting resin. When a pigment addition type photopolymerization system negative resist (hereinafter simply referred to as “a negative system resist”) is used as the dye addition type photo resist, after the negative system resist has been applied onto the wafer by utilizing the spin coating method, the negative system resist thus applied is subjected to pre-exposure baking. Also, the wafer is entirely exposed by using a reduction projection type stepper using an i-line (a spectrum line having a wavelength of 365 nm of mercury) as a light source to be subjected to post exposure baking, thereby carrying out the film deposition.

In processing in Step S14, as shown in FIG. 30D, the inorganic film 333 is formed as the green CF material 321G. Specifically, a P—SiO film, a P—SiN film, a P—SiON film or the like is formed as the inorganic film 333 at about 200° C. by utilizing a plasma Chemical Vapor Deposition (CVD) method. A refractive index of the inorganic film 333 thus formed herein can be generally adjusted to about 1.45 in the case of the P—SiO film, to about 1.90 in the case of the P—SiN film, and between 1.45 and 1.90 in the case of the P—SiON film. It is noted that although not illustrated in FIGS. 30A to 30K, when the microlenses 334 (refer to FIG. 25B) is directly formed on the inorganic film 333, it is supposed that the refractive index of the inorganic film 333 is adjusted so as to become equal to or smaller than that of the microlenses 334. As a result, it is possible to reduce the interface reflection.

In addition, a film deposition temperature of the film deposition by the plasma CVD method is set to be equal to or lower than 250° C., and is preferably set to be equal to or lower than 200° C. It is noted that a thickness of the inorganic film 333 is equal to or smaller than 200 nm, preferably 100 nm.

In processing in Step S15, as shown in FIG. 30E, a photo resist 361 is formed in an area corresponding to the green CF (the filter 321G) on the inorganic film 333. A novolac system positive resist (hereinafter simply referred to as “a positive resist”) using naphthoquinone diazide as a photosensitizing agent is used as a material of the photo resist 361. As far as the film deposition concerned, firstly, after the positive resist has been applied onto the inorganic film 333 by utilizing the spin coating method, the photo resist thus applied is subjected to the pre-exposure baking is exposed so as to have a predetermined pattern by using the reduction projection type stepper using an i-line (a spectrum line having a wavelength of 365 nm of mercury) as a light source, and is then the post exposure baking after the exposure is carried out. Next, a puddle development by a liquid solution of 2.38% tetramethylammonium hydroxide (TMAM) is carried out, and the post exposure baking is then carried out, thereby carrying out the film deposition. In this case, a developer in which an interface acting agent is added to the liquid solution of 2.38% TMAM may be used.

In processing in Step S16, a dry etching treatment is carried out with the photo resist 361 as an etching mask. A microwave plasma type etching system, a parallel plate type Reactive Ion Etching (RIE) system, a high-voltage narrowing gap type plasma etching system, an Electron Cyclotron Resonance (ECR) type etching system, a transformer linking plasma type etching system, an inductivity-coupled plasma type etching system or the like is used as an etching system. In addition, a helicon wave plasma type etching system or any of other high-density plasma type etching systems may also be used as the etching system. When the inductivity-coupled plasma type etching system, for example, is used as the etching system, as far as an etching gas concerned, one kind of any of fluorocarbon system gases such as CF₄, C₂F₆, C₃F₈, C₄F₈, CH₂F₂, and CHF₃ or plural kinds of gases of the fluorocarbon system gases such as CF₄, C₂F₆, C₃F₈, C₄F₈, CH₂F₂, and CHF₃ may be used or an etching gas in which a gas such as O₂, Ar, He or N₂ is added to these fluorocarbon system gases may also be used. In addition thereto, a gas in which a gas such as O₂ or N₂ is added to a halogen system gas such as Cl₂, BCl₃ or HBr may also be used as the etching gas.

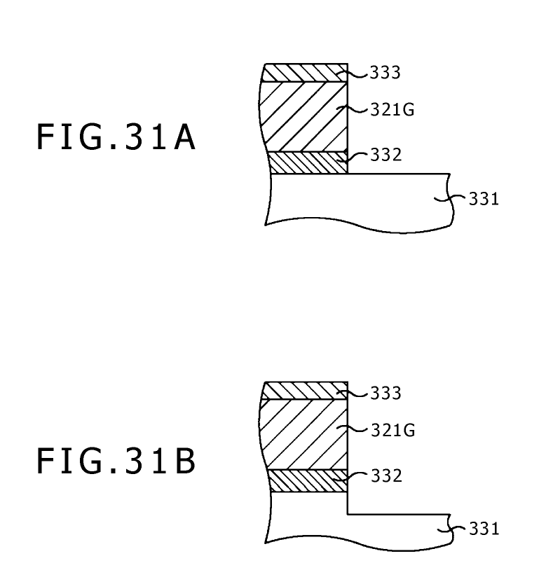

As a result, as shown in FIG. 30F, in an area other that an area in which the photo resist 361 is formed, that is, in an area other that an area in which the filter 321G is formed, the inorganic film 333, the CF material 321G, and the organic film 332 or selectively dry-etched away. It is noted that as far as this dry etching concerned, an emission spectrum of plasma generated when the inorganic film 331 is exposed is detected, thereby detecting an end point of the dry etching. The end point is precisely detected, thereby making it possible to adjust an over-etching amount. For example, as shown in an enlarged view in FIG. 31A of a portion, f, indicated by a broken line in FIG. 30F, a depth of the etching can be set so as to agree with a surface of the inorganic film 331. Or, likewise, as shown in an enlarged view in FIG. 31B, the depth of the etching can be adjusted to the middle of the inorganic film 331.

In addition, a thickness, t, of the photo resist 361 (refer to FIG. 30E) may be made either a thickness at which the remaining film of the photo resist 361 is removed away in a phase of completion of the dry etching, or a thickness at which the remaining film of the photo resist 361 is left in the phase of completion of the dry etching. When the remaining film of the photo resist 361 is left in the phase of completion of the dry etching, the remaining film concerned is removed away by using an organic solvent. In this case, a solvent such as N-methyl-2-pyrrolidone, γ-butylrolactone, cyclopemtanone, cyclohexanone, isophorone, N,N-dimethylacetamide, 1,3-dimethyl-2-imidazolidinone, tetramethylurea, dimethylsulfoxide, diethylene glycol dimethylether (diglyme), diethylene glycol diethylether, diethylene glycol dibutylether, propylene glycol monomethylether, propylene glycol monoethylether, dipropylene glycol monomethylethyer, propylene glycol monomethylether acetate, methyl lactate, butyl lactate, methyl-1,3-butylene glycol acetate, 1,3-butylene glycol-3-monomethylether, methyl pyruvate, ethyl pyruvate, or methyl-3-methoxypropionate, a mixed solvent containing therein two kinds or more of solvents described above, or the like is used as the organic solvent. In addition, a spin-on method in which the organic solvent described above is dropped onto a substrate while the substrate is rotated, thereby forming a uniform film by using a centrifugal force, a dipping method in which a substrate is dipped into the organic solvent described above, and is then drawn up, thereby forming a film or the like is used as a method of removing the remaining film of the photo resist 361.

By carrying out the processing until now, the inorganic film 333 is formed on the filter 321G, and four corners of the filter 321G are linked to the corners of the filters 321G adjacent thereto, respectively. Thus, the green CF pattern having a checkered pattern is formed in which an opening portion is provided in an area in which the filters 321R and 321B are formed.

In processing in Step S17, as shown in FIG. 30G, the light attenuating film 322 is formed in the green CF pattern having the checkered pattern. The light attenuating film 322 is composed of a metallic film. In this case, a transition metal such as tungsten (W), aluminum (Al), ruthenium (Ru), molybdenum (Mo), iridium (Ir), rhodium (Rh), chromium (Cr), or cobalt (Co) is used as the metal of the light attenuating film 322.

In this case, the light attenuating film 322 functions as a light reflection film for reflecting a light. It is noted that as far as the material of the light attenuating film 322 concerned, W is preferable from a viewpoint of a processing property, and Al is preferable from a viewpoint of a light reflection property. A sputtering method, for example, is used for the film deposition of the light attenuating film 322 as the metallic film. In this case, a substrate stage temperature is adjusted in such a way that a substrate temperature becomes equal to or lower than 100° C. In addition, 100 nm or less is preferable as a thickness of the light attenuating film 322.

In processing in Step S18, similarly to the case of the processing in Step S16 described above, the green CF pattern in which the light attenuating film 322 is formed is subjected to the entire surface dry etching processing.

By carrying out the processing until now, as shown in FIG. 30H, in the green CF pattern in which the four corners of the filter 321G are linked to the corners of the filters 321G adjacent thereto, respectively, the light attenuating film 322 is formed on a side surface (wall surface) of the opening portion in the area in which the filters 321R and 321B are formed.

In processing in Step S19, the red CF material 321R is applied to the entire surface of the green CF pattern in which the four corners of the filter 321G are linked by utilizing the spin coating method. The negative or positive dye addition type photo resist material is used as the red CF material 321R. In addition to a binder resin, a light radical generating agent, a monomer and the like as photosensitive components, a pigment dyestuff is contained with respect to a composition of the dye addition type photo resist material. In this case, it is supposed that the negative dye addition type photo resist material in which a portion to which a light is radiated is cured is used as the red CF material 321R.

The filter 321R is formed in such a way that an optical mask which transmits a light is formed only in the area in which the filter 321R is formed, the red CF material 321R is exposed by using the optical mask, and is then developed. At this time, an area which is wider than an area of the opening portion (an area in which the filter 321R is formed) is exposed in consideration of misalignment of the optical mask. Therefore, a part of the filter 321R is formed so as to overlap the inorganic film 333 on the filter 321G.

By carrying out this processing in Step S19, as shown in a left-hand side part of FIG. 30I, the red CF material 321R is buried in the opening portion of the area in which the filter 321R is formed in the green CF pattern in which the four corners of the filter 321G are linked to the corners of the filters 321G adjacent thereto, respectively.

In processing in Step S20, the blue CF material 321B is applied to the entire surface of the green CF pattern in which the four corners of the filter 321G are linked to the corners of the filters 321G adjacent thereto, respectively, by utilizing the spin coating method. The negative or positive dye addition type photo resist material is also used as the blue CF material 321B. In addition to a binder resin, a light radical generating agent, a monomer and the like as photosensitive components, a pigment dyestuff is contained with respect to a composition of the dye addition type photo resist material. In this case, it is supposed that the negative dye addition type photo resist material in which a portion to which a light is radiated is cured is used as the blue CF material 321B.

The filter 321B is formed in such a way that an optical mask which transmits a light is formed only in the area in which the filter 321B is formed, the blue CF material 321B is exposed by using the optical mask, and is then developed. At this time, an area which is wider than an area of the opening portion (an area in which the filter 321B is formed) is exposed in consideration of misalignment of the optical mask. Therefore, a part of the filter 321B is formed so as to overlap the inorganic film 333 on the filter 321G.

By carrying out this processing in Step S20, as shown in a right-hand side part of FIG. 30J, the blue CF material 321B is buried in the opening portion of the area in which the filter 321B is formed in the green CF pattern in which the four corners of the filter 321G are linked to the corners of the filters 321G adjacent thereto, respectively.

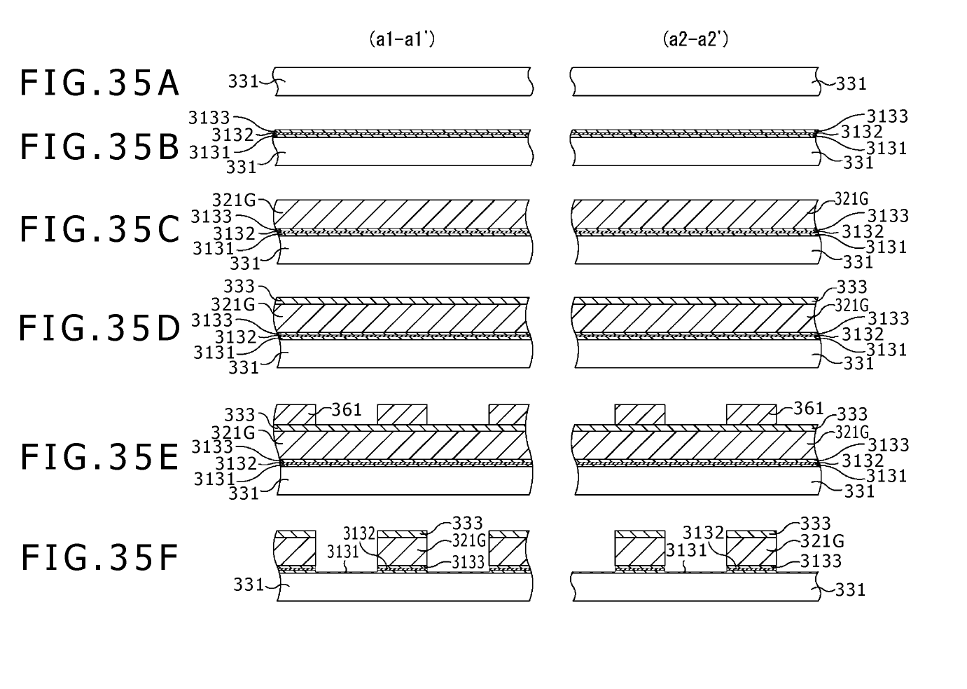

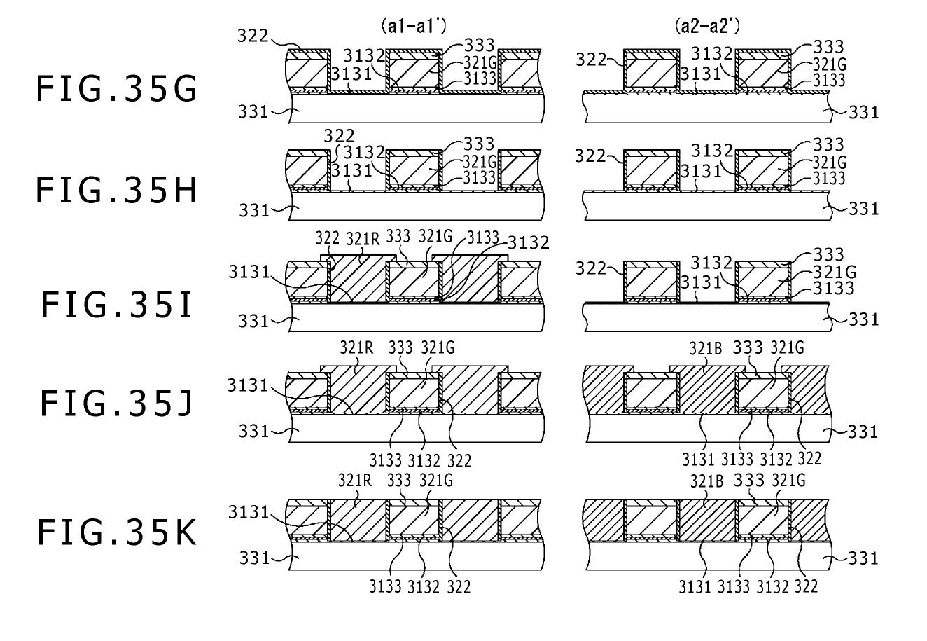

In processing in Step S21, as shown in FIG. 35K, a planarizing treatment is carried out for both of the red CF material 321R and the blue CF material 321B which are buried in the respective opening portions of the green CF pattern in which the four corners of the filter 321G are linked to the corners of the filters 321G adjacent thereto, respectively. Specifically, for example, both of the red CF material 321R and the blue CF material 321B are planarized by utilizing a Chemical Mechanical Polishing (CMP) method. In this CMP process, pH of a slurry liquid is set to the range of 7 to 14, a diameter of a slurry abrasive grain is set equal to or smaller than 100 nm, and a slurry abrasive grain concentration is set equal to or smaller than 5 wt %. In addition, a continuously foamed urethane resin or the like, for example, is used as a polishing pad. In this case, a polishing pressure is set equal to or smaller than 5 psi, and a rotation frequency of each of the polishing head and the polishing pad is set equal to or smaller than 150 rpm. It is noted that these values are suitably adjusted in such a way that the planarizing treatment is optimized. In addition, in this CMP process, the inorganic film 333 on the filter 321G has a role as a stopper.

It is noted that although the CMP process is carried out as the planarizing treatment for both of the red CF material 321R and the blue CF material 321B, alternatively, the dry etching which was carried out in the two pieces of processing in Step S16 and Step S18 may also be carried out.

According to the above processing from Step S11 to Step S21, the light attenuating film 322 is formed between the filter 321G, and the filter 321R and the filter 321B, and each of the bottom surfaces of the filter 321R and the filter 321B, and the light attenuating film 322 is formed lower than that of the filter 321G. As a result, it is possible to suppress the generation of the color mixture, and it is also possible to suppress the deterioration of the color reproducibility in the solid-state image pickup device.

In particular, the light attenuating film 22 is formed on the side surface (wall surface) of the opening portion in the area in which both of the filters 321R and 321B are formed in the CF pattern in which the four corners of the filter 321G are linked to the corners of the filters 321G adjacent thereto, respectively, in the self-align manner. Therefore, as compared with the existing technique such that after the light blocking body is formed, each of the CF materials is filled therein, the deterioration of the color reproducibility of the solid-state image pickup device can be suppressed with the more excellent processing precision.

In addition, although along with the scale down of the pixels in the solid-state image pickup device, the patterning characteristics has a tendency to be reduced, in such a case, the patterning characteristics have been adjusted until now by increasing the photosensitive components contained in the CF materials.

On the other hand, according to the present disclosure, each of the bottom surfaces of the filter 321R and the filter 321B, and the light attenuating film 322 is formed lower than that of the filter 321G. Therefore, each of the filter 321R and the filter 321B can be thickened in such a way that the desired spectral characteristics are obtained with respect to each of the filter 321R and the filter 321B. As a result, it is possible to obtain the more excellent patterning characteristics, and it is also possible to suppress the deterioration of both of the color reproducibility and the sensitivity characteristics without increasing the photosensitive components.

In addition, in the case where even when each of the filter 321R and the filter 321B is thickened, the desired spectral characteristics are not obtained with respect to each of the filter 321R and the filter 321B, and thus it is necessary to reduce the color concentrations, the adjustment is carried out in such a way that a rate of the dye in the red or blue CF material becomes small (that is, a rate of the photosensitive components becomes large), whereby it is possible to obtain the more excellent patterning characteristics. In this case, since the rate of the dye in the red or blue CF material can be reduced, it is also possible to suppress the cost.

### [Another Structures of Light Attenuating Film]

It is noted that although in the above structure, the description has been given with respect to the case where the light attenuating film 322 is composed of the metallic film, alternatively, the light attenuating film 322 may also be composed of an organic film (organic thermosetting film) containing therein a light absorbent. In this case, an acrylic, styrene system, epoxy system or siloxane system polyimide resin, or an organic material in which carbon black, titanium black, iron black or the like is contained as a light absorbent in a copolymerization system resin thereof or the like, for example, is used as the material of the organic thermosetting film.

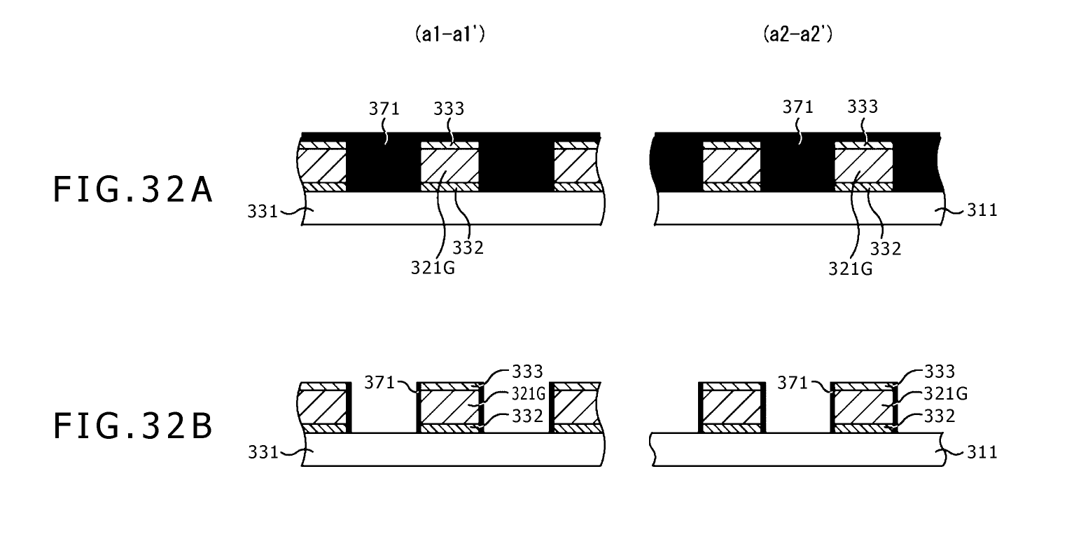

When the light attenuating film is composed of the organic film containing therein the light absorbent, in the processing in Step S17 of the flow chart shown in FIG. 29, as shown in FIG. 32A, a light attenuating film 371 is formed in the green CF pattern having the checkered pattern. The light attenuating film 371 as the organic system thermosetting film containing therein the light absorbent is formed in a heat treatment at about 150 to about 250° C. by utilizing the spin coating method.

In addition, in the processing in Step S18 of FIG. 29, similarly to the case of the processing in Step S16, the entire surface dry etching processing is carried out for the green CF pattern in which the light attenuating film 322 is formed. As a result, as shown in FIG. 32B, in the green CF pattern in which the four corners of the filter 321G are linked to the corners of the filters 321G adjacent thereto, respectively, the light attenuating film 371 is formed on the side surface (wall surface) of an opening portion in the area in which both of the filters 321R and 321B are formed. It is noted that in this case, the light attenuating film 371 functions as a light absorbing film for absorbing a light.

In the structure as well described above, it is possible to offer the same operation and effect as those of the color filter 321 shown in FIGS. 25A and 25B.

### [Another Structures of Color Filters (First Modification of Ninth Embodiment)]

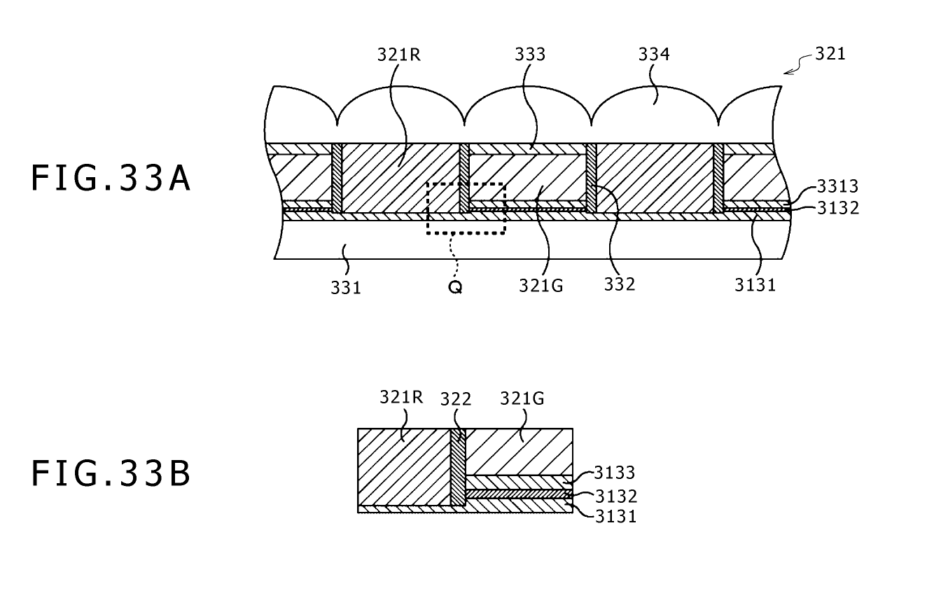

FIGS. 33A and 33B are respectively cross sectional views showing another structure of a color filter provided in a solid-state image pickup device according to a modification of the ninth embodiment to which the present disclosure is applied. Here, FIG. 33A is a cross sectional view of the color filter corresponding to the cross sectional view taken on line a1-a1′ of FIG. 25A. Also, FIG. 33B is an enlarged view of a portion Q indicated by a broken line in FIG. 33A.

It is noted that in the cross sectional views of FIGS. 33A and 33B, the same structures as those in the cross sectional view of FIG. 25B are designated by the same names and the same reference numerals or symbols, respectively, and a description thereof is suitably omitted here for the sake of simplicity.

As shown in FIGS. 33A and 33B, the color filters 321 (the filters 321R and 321G) are formed on an organic film 3131 formed on the inorganic film 331. However, the filter 321G is formed on an organic film 3133 on an inorganic film 3132 formed on the organic film 3131. As a result, the bottom surface of the filter 321R (the filter 321B) is formed lower than that of the filter 321G.

As described above, the color filter 321 shown in FIGS. 33A and 33B adopts a structure such that the organic film is formed on the lower side of each of the filter 321G, the filter 321R, and the filter 321G.

### [Processing for Forming Color Filters]

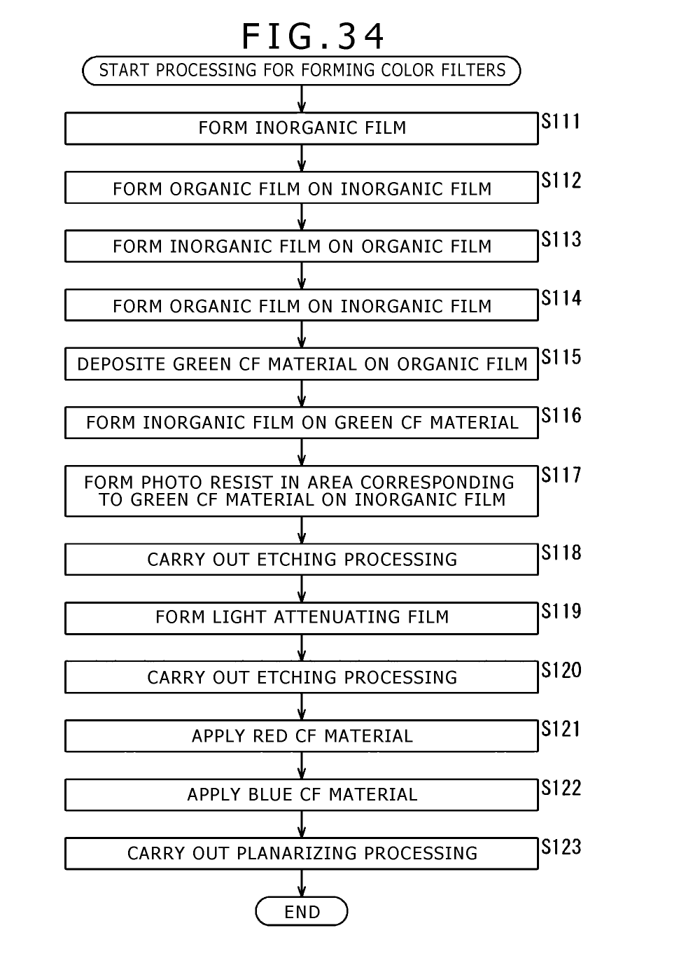

Next, processing for forming the color filters 321 in processes for manufacturing the solid-state image pickup device including the color filters 321 according to the first modification of the ninth embodiment will be described below with reference to FIG. 34 and FIGS. 35A to 35K. FIG. 34 is a flow chart explaining processing for forming the color filters 321 shown in FIGS. 33A and 33B. Also, FIGS. 35A to 35K are respectively cross sectional views of the color filters 321 in the forming processes. In particular, in each of FIGS. 35A to 35K, a left-hand side part thereof shows a cross sectional view of the color filter 321 corresponding to the cross sectional view taken on line a1-a1′ of FIG. 25A, and a right-hand side part thereof shows a cross sectional view taken on line b1-b1′ of FIG. 25A.

It is noted that since nine pieces of processing in Steps S111, S116, S117, and S119 to S123 of the flow chart shown in FIG. 34 are the same as those of processing in Steps S11, S14, S15, and S17 to S21 of the flow chart shown in FIG. 29, respectively, a description thereof is omitted here for the sake of simplicity.

In processing in Step S112, the organic film 3131 is formed on the inorganic film 331. Specifically, for example, an acrylic, styrene system or an epoxy system resin is formed as the organic film 3131 in a heat treatment at about 150° C. to about 250° C. on the inorganic film 331 by utilizing the spin coating method. It is noted that a thickness of the organic film 3131 is preferably equal to or smaller than 200 nm.

In processing in Step S113, the inorganic film 3132 is formed on the organic film 3131. Specifically, a P—Si film, a P—SiN film, a P—SiON film or the like, for example, is formed as the inorganic film 3132. It is noted that a thickness of the inorganic film 3132 is preferably equal to or smaller than 200 nm.

In processing in Step S114, the organic film 3133 is formed on the inorganic film 3132. Specifically, for example, an acrylic, styrene system or an epoxy system resin is formed as the organic film 3133 in a heat treatment at about 150° C. to about 250° C. on the inorganic film 3132 by utilizing the spin coating method. It is noted that a thickness of the organic film 3133 is preferably equal to or smaller than 200 nm.

In such a manner, as shown in FIG. 35B, the organic film 3131 is formed on the inorganic film 331, the inorganic film 3132 is formed on the organic film 3131, and the organic film 3133 is formed on the inorganic film 3132. It is noted that when each of the organic film 3131 and the organic film 3133 is composed of an acrylic resin, using the P—SiO film as the inorganic film 3132 results in that a refractive index of the inorganic film 3132 can be made approximately equal to that (about 1.5) of each of the organic film 3131 and the organic film 3133, thereby making it possible to reduce the interface reflection.

Also, in the processing in Step S115, as shown in FIG. 35C, the green CF material 321G is deposited on the organic film 3133. Since details of the film deposition are the same as those in the processing in Step S13 of the flow chart shown in FIG. 29, a description thereof is omitted here for the sake of simplicity.

In addition, in processing in Step S118, similarly to the case of the processing in Step S16 of the flow chart shown in FIG. 29, the dry etching processing is carried out with the photo resist 361 as an etching mask.

As a result, as shown in FIG. 35F, in an area other than an area in which the photo resist 361 is formed, that is, an area other than an area in which the filter 321G is formed, the inorganic film 333, the CF material 321G, the organic film 3133, the inorganic film 3132, and the organic film 3131 are all selectively dry-etched away. It is noted that for this dry etching process, an end point of the dry etching is detected based on the inorganic film 3132. Specifically, the change in the emission spectrum of the plasma generated when the inorganic film 3132 is exposed, and the change in the emission spectrum of the plasma generated when the organic film 3131 is exposed are both detected, thereby adjusting the etching amount. Thus, the depth of the etching can be adjusted to the middle of the organic film 3131.

As a result, as shown in FIGS. 35I, 35J, and 35K, both of the filter 321R and the filter 321B are formed on the organic film 3131.

In the color filter forming processing as well shown as the flow chart of FIG. 34, it is possible to offer the same operation and effect as those in the color filter forming processing shown as the flow chart of FIG. 29.

It is noted that although in the color filter forming processing shown as the flow chart of FIG. 29, both of the filter 321R and the filter 321B are formed on the inorganic film 331, the adhesiveness between each of the filter 321R and the filter 321B, and the inorganic film 331 is reduced depending on the material of the dye addition type photoresist composing each of the filter 321R and the filter 321B in some cases.

In order to cope with such a situation, in the color filter forming processing shown as the flow chart of FIG. 34, both of the filter 321R and the filter 321B are formed on the inorganic film 3131, whereby it is possible to increase the adhesiveness between each of the filter 321R and the filter 321B, and the organic film 3131.

### [Color Filters of Other Arrangements (Second and Third Modifications)]

Although the description has been given so far with respect to the ninth embodiment in which the present disclosure is applied to the solid-state image pickup device including the color filters in which the filters corresponding to the three primary colors: R, G, and B corresponding to plural pixels, respectively, are disposed in the Bayer arrangement, the present disclosure may also be applied to a solid-state image pickup device including color filters having any other suitable arrangement.

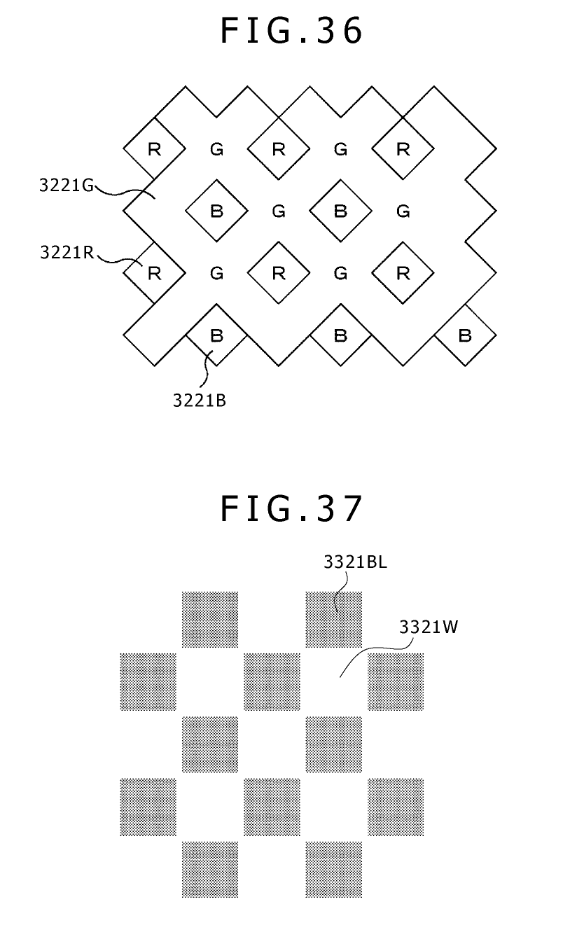

For example, as shown in FIG. 36, the present disclosure may also be applied to a solid-state image pickup device including color filters composed of green color filters 3221G which are formed in a lattice, and red color filters 3221R and blue color filters 3221B which are formed in areas of eyes of the lattice, respectively. In the color filters as well shown in FIG. 36, the areas in which the green color filters 3221G are formed, respectively, are linked to one another in at least parts thereof. In this case, the solid-state image pickup device including the color filters shown in FIG. 36 is a second modification of the ninth embodiment of the present disclosure.

In addition, the present disclosure may also be applied to a solid-state image pickup device including filters, for obtaining a monochrome image, in which as shown in FIG. 37, the G color filters in the color filters exhibiting the Bayer arrangement are made as filters 3321W which correspond to white pixels, respectively, and which transmit all of the lights in the visible light range, and the R and B color filters are made as filters 3321BL corresponding to black pixels, respectively. In this case, the solid-state image pickup device including the filters shown in FIG. 37 is a third modification of the ninth embodiment of the present disclosure.

It is noted that the embodiments of the present disclosure is by no means limited to the embodiments described above and thus various kinds of changes can be made without departing from the subject matter of the present disclosure.

### 12. Tenth Embodiment

### Electronic Apparatus

The solid-state image pickup element 1 described above can be applied to various kinds of electronic apparatuses such as an image pickup apparatus such as a digital still camera or a digital video camera, a mobile phone including an image pickup capturing function, and other apparatuses each including an image capturing function.

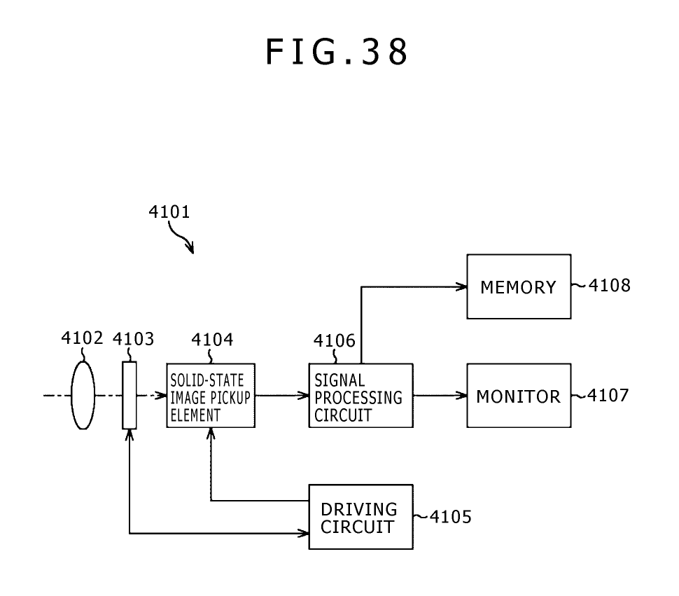

FIG. 38 is a block diagram showing a configuration of an image pickup apparatus as an electronic apparatus according to a tenth embodiment of the present disclosure to which the present disclosure is applied.

An image pickup apparatus 4101 shown in FIG. 38 includes an optical system 4102, a shutter arrangement 4103, a solid-state image pickup element 4104, a driving circuit 4105, a signal processing circuit 4106, a monitor 4107, and a memory 4108. In this case, the image pickup apparatus 4101 can capture both of a still image and a moving image.

The optical system 4102 is composed of one or plural sheets of lenses. In this case, the optical system 4102 guides a light (incident light) from a subject to image the light on an acceptance surface (a light receiving area 22: refer to FIG. 2) of the solid-state image pickup element 4104.

The shutter arrangement 4103 is disposed between the optical system 4102 and the solid-state image pickup element 4104, and controls both of a period of time for light radiation, and a period of time for light blocking for the solid-state image pickup element 4104 in accordance with the control made by the driving circuit 4105.

The solid-state image pickup element 4104 is composed of the solid-state image pickup element 1 according to the first embodiment of the present disclosure described above. The solid-state image pickup element 4104 accumulates therein the signal electric charges for a given period of time in correspondence to the light imaged on the acceptance surface through both of the optical system 4102 and the shutter arrangement 4103. The signal electric charges accumulated in the solid-state image pickup element 4104 are transferred in accordance with the signal (timing signal) supplied from the driving circuit 4105. The solid-state image pickup element 4104 either may be configured in the form of one chip by itself, or may be configured as a part of a camera module which is packaged together with the optical system 4102, the shutter arrangement 4103, the solid-state image pickup element 4104, the signal processing circuit 4106, and the like.

The driving circuit 4105 outputs a drive signal in accordance with which both of a transferring operation of the solid-state image pickup element 4104, and a shutter operation of the shutter arrangement 4103 are controlled, thereby driving both of the solid-state image pickup element 4104 and the shutter arrangement 4103.

The signal processing circuit 4106 executes various kinds of processing for the signal electric charges outputted from the solid-state image pickup element 4104. The image data obtained through the signal processing by the signal processing circuit 4106 is supplied to the monitor 4107 which in turn displays thereon the image based on the image data or is supplied to the memory 4108 to be stored (recorded) therein.

In the solid-state image pickup apparatus 4101 configured in such a manner, the solid-state image pickup element 1 in which the sensitivity characteristics are improved in the manner as described above is applied to the solid-state image pickup element 4104, thereby making it possible to enhance the image quality.

It is noted that although in the tenth embodiment described above, the description has been given with respect to the case where the solid-state image pickup element 1 is composed of the back surface radiation type CMOS solid-state image pickup element, the present disclosure can also be applied to the solid-state image pickup element composed of any of the surface type solid-state image pickup element or the CCD type solid-state image pickup element.

Also, although in the tenth embodiment of the present disclosure, the solid-state image pickup element 4104 is composed of the solid-state image pickup element 1 according to the first embodiment of the present disclosure, alternatively, the solid-state image pickup element 4104 may also be composed of any of the solid-state image pickup elements according to the second to eighth embodiment of the present disclosure.

The present technology contains subject matter related to those disclosed in Japanese Priority Patent Applications JP 2011-231640, JP 2011-262101, and JP 2011-268895 filed in the Japan Patent Office respectively on Oct. 21, 2011, Nov. 30, 2011, and Dec. 8, 2011, the entire contents of which are hereby incorporated by reference.

What is claimed is:

1. A method of manufacturing a solid-state image pickup element having a lens provided above a light receiving portion, the manufacturing method comprising:
forming a lens base material layer composing the lens;
forming an intermediate film having a thermal expansion coefficient larger than that of a resist on the lens base material layer;
forming the resist in contact with the intermediate film;
forming the resist into a lens shape by thermal reflow; and
transferring the lens shape of the resist to the lens base material layer by etching, thereby forming the lens.

2. The method of manufacturing a solid-state image pickup element, according to claim 1, wherein the intermediate film is formed so as to have a thickness of 0.3 μm or less.

3. A method of manufacturing a solid-state image pickup element having a lens provided above a light receiving portion, the manufacturing method comprising:
forming an intermediate film having a thermal expansion coefficient larger than that of a resist;
forming the resist in contact with the intermediate film; and
forming the resist into a lens shape by thermal reflow, thereby forming the lens composed of the resist.

4. The method of manufacturing a solid-state image pickup element, according to claim 3, wherein the intermediate film is formed so as to have a thickness of 0.3 μm or less.

5. A solid-state image pickup element, comprising:
a light receiving portion formed in a semiconductor substrate;
an intermediate film having a thermal exposure coefficient larger than that of a resist and formed above the light receiving portion; and
a lens composed of the resist and formed in contact with the intermediate film.

6. The solid-state image pickup element according to claim 5, wherein the intermediate film is formed so as to have a thickness of 0.3 μm or less.

7. An image pickup device, comprising:
an optical system;
a solid-state image pickup element having a light receiving portion formed in a semiconductor substrate, an intermediate film having a thermal expansion coefficient larger than that of a resist and formed above the light receiving portion, and a lens composed of the resist and formed in contact with the intermediate film; and
a signal processing circuit processing an output signal from the solid-state image pickup element.

8. A solid-state image pickup element, comprising:
a pixel area having an effective pixel area, and a non-effective pixel area other than the effective pixel area,
wherein each of pixels within the effective pixel area includes a cover film made of one of an inorganic material or an organic material, and a microlens made of the other of the inorganic material or the organic material on a color filter, and
the color film is formed in the non-effective pixel area as well.

9. The solid-state image pickup element according to claim 8, wherein the cover film is exposed in a gap defined between the microlenses adjacent to each other in a diagonal direction.

10. The solid-state image pickup element according to claim 8, wherein a height of a base in which the cover film of the non-effective pixel area is equal to or higher than an upper surface of the color filter of the effective pixel area.

11. The solid-state image pickup element according to claim 8, wherein the cover film of the non-effective pixel area is formed on the color filter.

12. The solid-state image pickup element according to claim 8, wherein
the color filters are disposed in a Bayer arrangement, and
the green color filter is linked to the green color filters adjacent thereto in a diagonal direction in four corners, and each of linking portions thereof is formed more thinly than any of other areas of the color filters.

13. The solid-state image pickup element according to claim 8, wherein
the inorganic material is one of an oxide film, a nitride film, an oxynitride film or a silicon carbide film, and
the organic material is a novolac system resin, an acrylic resin, a styrene series resin, or plural copolymerization system resins of them.

14. A method of manufacturing a solid-state image pickup element, comprising:
of a pixel area having an effective pixel area and a non-effective pixel area other than the effective pixel area, after forming a color filter in each of pixels within the effective pixel area, forming a cover film made of one of an inorganic material or an organic material in the effective pixel area and the non-effective pixel area;
forming a lens material layer made of the other of the inorganic material or the organic material as a material of a microlens on the cover film in the effective pixel area; and
detecting exposure of the cover film in etching with which the lens material layer is formed into a lens shape, thereby ending the etching.

15. The method of manufacturing a solid-state image pickup element, according to claim 14, wherein
the color filters are disposed in a Bayer arrangement,
the green color filter is linked to the green color filters adjacent thereto in a diagonal direction in four corners, and each of linking portions thereof is formed more thinly any of other areas of the color filters, and
after a lapse of a predetermined time from detection of exposure of the cover film to exposure of the cover film of the linking portion.

16. The method of manufacturing a solid-state image pickup element, according to claim 15, wherein the green color filter is patterned by using a photo mask which is made in such a way that a pattern size of each of the linking portions is set to a resolution limit or less of a photosensitive resin.

17. An electronic apparatus, comprising:
a pixel area having an effective pixel area and a non-effective pixel area other than the effective pixel area,
wherein each of pixels within the effective pixel area includes a cover film made of one of an inorganic material or an organic material, and a microlens made of the other of the inorganic material or the organic material on a color film, and
the cover film is formed in the non-effective pixel area as well.

18. A solid-state image pickup device, including
a color filter comprising:
a filter having a predetermined color component corresponding to a predetermined pixel of plural pixels formed in a lattice;
filters having other color components corresponding to other pixels, respectively, and formed in each of areas other than areas in each of which the filter having the predetermined color component is formed; and
a light attenuating film attenuating a light transmittance and formed in a boundary between the filter having the predetermined color component and the filters having other color components,
wherein the areas in each of which the filter having the predetermined color component is formed are linked to one another in at least parts thereof, and
a bottom surface of each of the filters having other color components and the light attenuating film is lower than that of the filter having the predetermined color filter.

19. The solid-state image pickup device according to claim 18, wherein, in the color filter,
a material of the filter having the predetermined color component is formed on an organic film formed on an inorganic film,
a photo resist is formed in an area in which the filter having the predetermined color component is formed, and etching processing is carried out for the material of the filter having the predetermined color component,
the light attenuating film is formed in the filter having the predetermined color component for which the etching processing is carried out,
etching processing is carried out for the filter having the predetermined color component in which the light attenuating film is formed, and
materials of the filters having other color components are applied, thereby forming the color filter.

20. The solid-state image pickup device according to claim 19, wherein, the material of the filter having the predetermined color component is deposited on a second organic film formed on a second inorganic film on a first organic film formed on a first inorganic film, to be formed on the color filter.

21. The solid-state image pickup device according to claim 19, wherein in the color filter, other inorganic films are formed on the filter having the predetermined color component; and
each of upper surfaces of the other inorganic films, and each of upper surfaces of the filters having other color components are made flush with each other.

22. The solid-state image pickup device according to claim 21, further comprising:
a microlens on an upper surface of the color filter,
wherein a refractive index of each of the other inorganic films is equal to or smaller than that of the microlens.

23. The solid-state image pickup device according to claim 18, wherein, in the color filter, the light attenuating film is composed of a metallic film.

24. The solid-state image pickup device according to claim 18, wherein, in the color filter, the light attenuating film is composed of an inorganic film containing therein a light absorbing material.

25. The solid-state image pickup device according to claim 18, wherein, in the color filter, the filter having the predetermined color component and the filters having other color components are disposed in a Bayer arrangement.

26. A method of manufacturing a solid-state image pickup device including
a filter having a predetermined color component corresponding to a predetermined pixel of plural pixels formed in a lattice,
filters having other color components corresponding to other pixels, respectively, and formed in each of areas other than areas in each of which the filter having the predetermined color component is formed, and
a light attenuating film attenuating a light transmittance and formed in a boundary between the filter having the predetermined color component and the filters having other color components,
wherein the areas in each of which the filter having the predetermined color component is formed are linked to one another in at least parts thereof, and
a bottom surface of each of the filters having other color components and the light attenuating film is lower than that of the filter having the predetermined color filter,
the manufacturing method comprising:
depositing a material for the filter having the predetermined color component on an organic film formed on an inorganic film;
forming a photo resist in the areas in each of which the filter having the predetermined color component is formed, and carrying out etching processing for the material for the filter having the predetermined color component;
forming the light attenuating film in the filter having the predetermined color component for which the etching processing is carried out;
carrying out etching processing for the filter having the predetermined color component in which the light attenuating film is formed; and
applying materials for the filters having other color components, respectively.
